(19) United States
(12) Patent Application Publication
(10) Pub. No.: US 2026/0040938 A1
(43) Pub. Date: Feb. 5, 2026

(54) SEMICONDUCTOR MEMORY DEVICE

(71) Applicant: Kioxia Corporation, Tokyo (JP)

(72) Inventor: Ken KOMIYA, Nagoya (JP)

(73) Assignee: Kioxia Corporation, Tokyo (JP)

(21) Appl. No.: 18/980,955

(22) Filed: Dec. 13, 2024

(30) Foreign Application Priority Data
Jul. 30, 2024 (JP) 2024-123479

(51) Int. Cl. H01L 23/528; G11C 8/14; H10B 41/41; H10B 43/40

(52) U.S. Cl. CPC H01L 23/5283; G11C 8/14; H10B 41/41; H10B 43/40

(57) ABSTRACT

According to one embodiment, a semiconductor memory device includes the following structure. First word lines are stacked above a substrate. Second word lines are stacked above the first word lines. A selection gate line is provided above the second word lines. A first pillar penetrates the first word lines in a first direction orthogonal to an upper surface of the substrate. A second pillar penetrates the second word lines and the selection gate line in the first direction. The second word lines include an upper word line disposed around an upper layer portion of the second pillar, a middle word line disposed around a middle layer portion below the upper layer portion, and a lower word line disposed around a lower layer portion below the middle layer portion. A film thickness of the upper word line is thicker than that of the middle word line.

### CROSS-REFERENCE TO RELATED APPLICATIONS

This application is based upon and claims the benefit of priority from Japanese Patent Application No. 2024-123479, filed Jul. 30, 2024, the entire contents of which are incorporated herein by reference.

### FIELD

Embodiments described herein relate generally to a semiconductor memory device.

### BACKGROUND

A NAND flash memory capable of storing data in a nonvolatile manner is known.

### BRIEF DESCRIPTION OF THE DRAWINGS

FIG. 1 is a block diagram showing a circuit configuration of a semiconductor memory device according to a first embodiment.

FIG. 2 is a circuit diagram of a block of a memory cell array according to the first embodiment.

FIG. 3 is a diagram showing a planar layout of the semiconductor memory device according to the first embodiment.

FIG. 4 is a diagram for explaining a cross-sectional structure of a memory region according to the first embodiment.

FIG. 5 is a cross-sectional view taken along the line V-V in FIG. 4.

FIG. 6 is a view for explaining a cross-sectional structure of a hookup region according to the first embodiment.

FIG. 7 is a cross-sectional view showing an outline of structures of memory pillars and word lines according to the first embodiment.

FIG. 8 is a cross-sectional view showing details of the structures of the memory pillars and the word lines according to the first embodiment.

FIG. 9 is a flowchart showing a method of manufacturing contacts of the semiconductor memory device according to the first embodiment.

FIGS. 10 to 14 are cross-sectional views showing the method of manufacturing the contacts of the semiconductor memory device according to the first embodiment.

FIG. 15 is a cross-sectional view showing an outline of structures of memory pillars and word lines according to a second embodiment.

FIG. 16 is a cross-sectional view showing details of the structures of the memory pillars and the word lines according to the second embodiment.

FIG. 17 is a cross-sectional view showing an outline of structures of the memory pillars and the word lines according to a first modification of the second embodiment.

FIG. 18 is a cross-sectional view showing an outline of structures of the memory pillars and the word lines according to a second modification of the second embodiment.

FIG. 19 is a cross-sectional view showing an outline of structures of memory pillars and word lines according to a third embodiment.

FIG. 20 is a cross-sectional view showing details of the structures of the memory pillars and the word lines according to the third embodiment.

### DETAILED DESCRIPTION

In general, according to one embodiment, a semiconductor memory device includes a first plurality of word lines, a second plurality of word lines, a selection gate line, a first pillar and a second pillar. The first plurality of word lines are stacked above a substrate. The second plurality of word lines are stacked above the first plurality of word lines. The selection gate line is provided above the second plurality of word lines. The first pillar is provided above the substrate and penetrating the first plurality of word lines in a first direction orthogonal to an upper surface of the substrate. The second pillar is provided above the first pillar and penetrating the second plurality of word lines and the selection gate line in the first direction. The second plurality of word lines include an upper word line disposed around an upper layer portion of the second pillar, a middle word line disposed around a middle layer portion below the upper layer portion, and a lower word line disposed around a lower layer portion below the middle layer portion. A film thickness of the upper word line is thicker than a film thickness of the middle word line.

In the following description, components having same function and configuration are denoted by same reference numerals. In addition, the following embodiments exemplify an apparatus and a method for embodying the technical idea of the embodiments, and do not specify the material, shape, structure, arrangement, and the like of the components as follows.

Hereinafter, a semiconductor memory device according to an embodiment will be described. An example of the semiconductor memory device is a three-dimensional stacked NAND flash memory in which memory cell transistors are three-dimensionally stacked above a semiconductor substrate. The NAND flash memory is a semiconductor memory capable of storing data in a nonvolatile manner.

For example, in a semiconductor memory device, a plurality of word lines are stacked on a substrate, and a row decoder for supplying voltage to the word lines is provided. Memory pillars are formed in the stacking direction of the word lines so as to penetrate the word lines. At an end of the word line, a contact for connecting the word line to the row decoder is formed.

In the formation of the contact, in a case where a contact hole is processed, the contact hole may pass through the target word line and reach the word line located below, or may reach the vicinity of the word line below. In such a case, a problem such as a short circuit between upper and lower word lines may occur in inspection before shipment or use after shipment.

According to the embodiment, the film thicknesses of the word lines of some layers among the stacked word lines are thickened. This reduces the occurrence of the above-described problem. Some embodiments are described below.

### 1. First Embodiment

A semiconductor memory device according to a first embodiment will be described.

### 1.1 Circuit Configuration of Semiconductor Memory Device

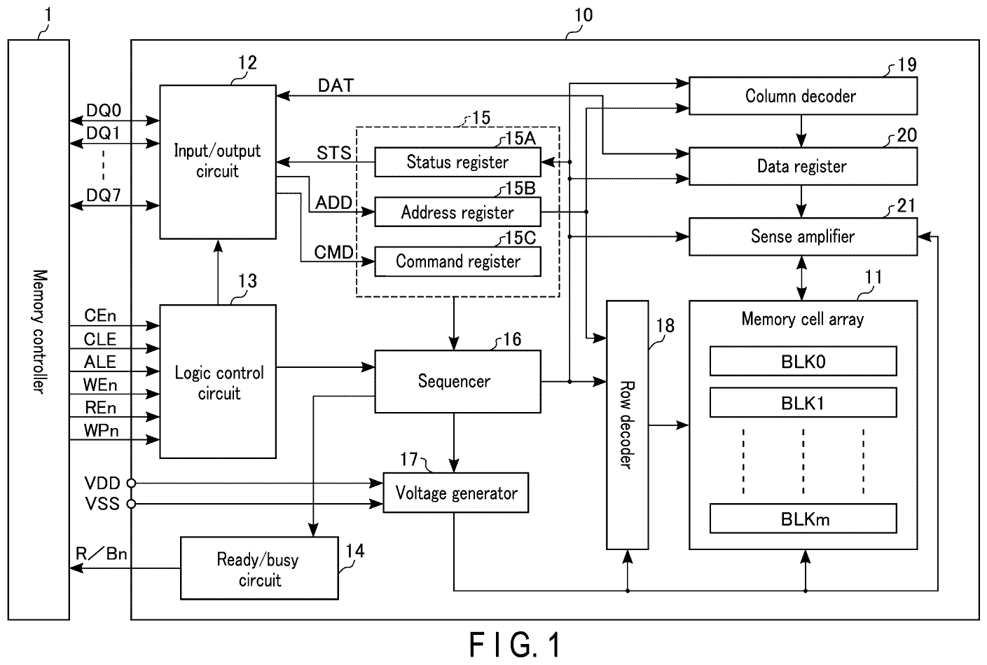

First, a circuit configuration of the semiconductor memory device according to the first embodiment will be described. FIG. 1 is a block diagram showing the circuit configuration of the semiconductor memory device according to the first embodiment.

A semiconductor memory device 10 according to the first embodiment includes, for example, a NAND flash memory, and stores data in a nonvolatile manner. To the semiconductor memory device 10, a memory controller 1 is connected via a NAND bus. The semiconductor memory device 10 is controlled by the memory controller 1.

The semiconductor memory device 10 includes a memory cell array 11, an input/output circuit 12, a logic control circuit 13, a ready/busy circuit 14, a register group 15, a sequencer (or, a control circuit) 16, a voltage generator 17, a row decoder 18, a column decoder 19, a data register 20, and a sense amplifier 21. The register group 15 includes a status register 15A, an address register 15B, and a command register 15C.

The memory cell array 11 includes one or more blocks BLK0, BLK1, BLK2, . . . , and BLKn (n is an integer that is zero or more). Each of the blocks BLK0 to BLKn includes a plurality of memory cell transistors (hereinafter, also referred to as a memory cell) associated with a row and a column respectively. The memory cell transistor is an electrically erasable/programmable non-volatile memory cell. The memory cell array 11 includes a plurality of word lines, a plurality of bit lines, and a source line for applying a voltage to the memory cell transistor. A specific configuration of the block BLKn will be described later.

The input/output circuit 12 and the logic control circuit 13 are connected to the memory controller 1 via input/output terminals (or the NAND bus). The input/output circuit 12 transmits and receives an I/O signal DQ (for example, DQ0, DQ1, DQ2, . . . , DQ7) to and from the memory controller 1 via the input/output terminal. The I/O signal DQ communicates a command, an address, data, and the like.

The logic control circuit 13 receives an external control signal from the memory controller 1 via the input/output terminal (or the NAND bus). The external control signal includes, for example, a chip enable signal CEn, a command latch enable signal CLE, an address latch enable signal ALE, a write enable signal WEn, a read enable signal REn, and a write protect signal WPn. “n” appended to the signal name indicates that the signal is active low.

In a case where a plurality of semiconductor memory devices 10 is mounted, the chip enable signal CEn enables selection of the semiconductor memory device 10 and is asserted in a case where the semiconductor memory device 10 is selected. The command latch enable signal CLE enables a command transmitted as the signal DQ to be latched in the command register 15C. The address latch enable signal ALE allows the address register 15B to latch an address to be transmitted as the signal DQ. The write enable signal WEn enables data transmitted as the signal DQ to be stored in the input/output circuit 12. The read enable signal REn enables data read from the memory cell array 11 to be output as a signal DQ. The write protect signal WPn is asserted in a case where a write operation and an erase operation to the semiconductor memory device 10 are prohibited.

The ready/busy circuit 14 generates a ready/busy signal R/Bn under the control of the sequencer 16. The ready/busy signal R/Bn indicates whether the semiconductor memory device 10 is in a ready state or a busy state. The ready state indicates a state in which the semiconductor memory device 10 can receive an instruction from the memory controller 1. The busy state indicates a state in which the semiconductor memory device 10 cannot accept an instruction from the memory controller 1. The memory controller 1 can recognize whether the semiconductor memory device 10 is in the ready state or the busy state by receiving the ready/busy signal R/Bn from the semiconductor memory device 10.

The status register 15A stores status information STS necessary for the operation of the semiconductor memory device 10. The status register 15A transfers the status information STS to the input/output circuit 12 according to an instruction from the sequencer 16.

The address register 15B stores an address ADD transferred from the input/output circuit 12. The address ADD includes a row address and a column address. The row address includes, for example, a block address designating the block BLKn to be operated and a page address designating the word line WL to be operated in the designated block.

The command register 15C stores a command CMD transferred from the input/output circuit 12. The command CMD includes, for example, a write command instructing the sequencer 16 to perform a write operation, a read command instructing a read operation, and an erase command instructing an erase operation.

For example, a static random access memory (SRAM) is used for the status register 15A, the address register 15B, and the command register 15C.

The sequencer 16 receives a command from the command register 15C and comprehensively controls the semiconductor memory device 10 according to a sequence based on the command.

The sequencer 16 controls the voltage generator 17, the row decoder 18, the column decoder 19, the data register 20, the sense amplifier 21, and the like to execute the write operation, the read operation, and the erase operation. Specifically, the sequencer 16 controls the voltage generator 17, the row decoder 18, the data register 20, and the sense amplifier 21 and writes data in the memory cell transistors designated by the address ADD based on the write command received from the command register 15C. The sequencer 16 controls the voltage generator 17, the row decoder 18, the column decoder 19, the data register 20, and the sense amplifier 21 and reads data from the memory cell transistors designated by the address ADD based on the read command received from the command register 15C. The sequencer 16 controls the voltage generator 17, the row decoder 18, the column decoder 19, the data register 20, and the sense amplifier 21 and erases the data stored in the block designated by the address ADD based on the erase command received from the command register 15C. Note that a circuit including the column decoder 19, the data register 20, and the like is referred to as a column system control circuit.

The voltage generator 17 receives a power supply voltage VDD and a ground voltage VSS from the outside of the semiconductor memory device 10 via a power supply terminal. The power supply voltage VDD is an external voltage supplied from the outside of the semiconductor memory device 10. The ground voltage VSS is an external voltage supplied from the outside of the semiconductor memory device 10, and is, for example, 0 V.

The voltage generator 17 generates a plurality of types of voltage necessary for the write operation, the read operation, and the erase operation using the power supply voltage VDD. The voltage generator 17 supplies the generated voltage to the memory cell array 11, the row decoder 18, the sense amplifier 21, and the like.

The row decoder 18 receives a row address from the address register 15B and decodes the row address. The row decoder 18 selects one of the plurality of blocks based on the decoding result of the row address, and further selects the word line WL in the selected block BLKn. Further, the row decoder 18 transfers the plurality of types of voltage supplied from the voltage generator 17 to the selected block BLKn.

The column decoder 19 receives a column address from the address register 15B and decodes the column address. The column decoder 19 selects the latch circuit in the data register 20 based on the decoding result of the column address.

The data register 20 includes a plurality of latch circuits. The latch circuit temporarily stores write data or read data.

The sense amplifier 21 senses and amplifies data read from the memory cell transistor to the bit line during a data read operation. Further, the sense amplifier 21 temporarily stores read data DAT read from the memory cell transistor and transfers the stored read data DAT to the data register 20. In addition, the sense amplifier 21 temporarily stores the write data DAT transferred from the input/output circuit 12 via the data register 20 at the time of the data write operation. Further, the sense amplifier 21 transfers the write data DAT to the bit line.

Next, a circuit configuration of the memory cell array 11 in the semiconductor memory device 10 according to the first embodiment will be described. As described above, the memory cell array 11 includes a plurality of blocks BLK0 to BLKn. Hereinafter, a circuit configuration of the block BLKn will be described.

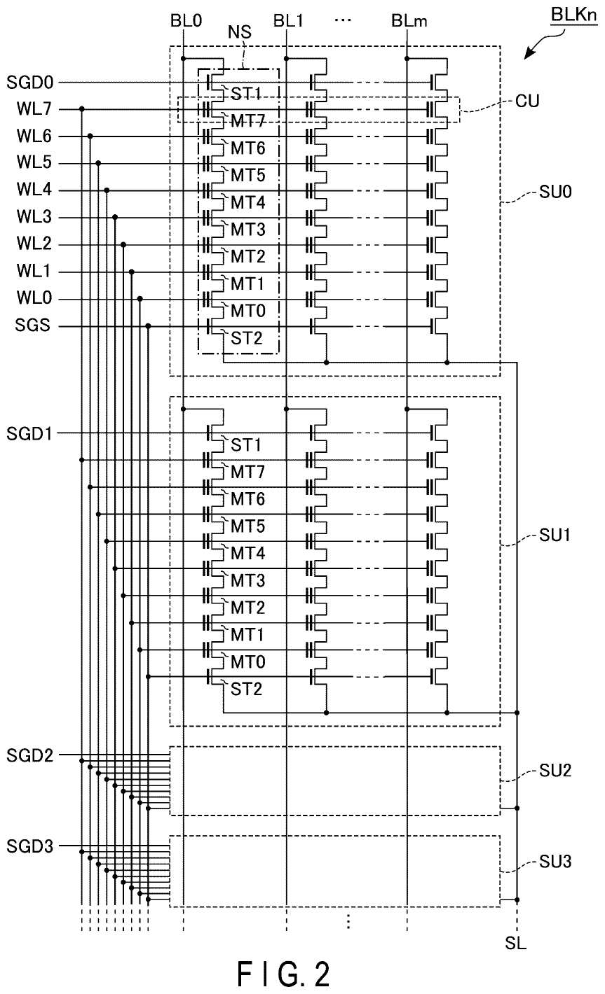

FIG. 2 is a circuit diagram of the block BLKn in the memory cell array 11. The block BLKn includes, for example, a plurality of string units SU0, SU1, SU2, and SU3. Hereinafter, the string unit SU indicates each of the string units SU0 to SU3. The string unit SU includes a plurality of NAND strings (or a memory string) NS.

Here, for ease of description, an example in which the NAND string NS includes, for example, eight memory cell transistors MT0, MT1, MT2, . . . , and MT7 and two selection transistors ST1 and ST2 will be described. Hereinafter, the memory cell transistor MT indicates each of the memory cell transistors MT0 to MT7.

The memory cell transistor MT includes a control gate and a charge storage layer, and stores data in a nonvolatile manner. The memory cell transistors MT0 to MT7 are connected in series between a source of the selection transistor ST1 and a drain of the selection transistor ST2. The memory cell transistor MT can store 1-bit data or data in 2-bit or more.

A plurality of gates of the selection transistors ST1 included in the string unit SU0 are connected to a selection gate line SGD0. Similarly, the gates of the selection transistors ST1 of the string units SU1 to SU3 are connected to selection gate lines SGD1 to SGD3, respectively. Each of the selection gate lines SGD0 to SGD3 is independently controlled by the row decoder 18.

A plurality of gates of the selection transistor ST2 included in the string unit SU0 are connected to a selection gate line SGS. Similarly, the gates of the selection transistors ST2 of each of the string units SU1 to SU3 are connected to the selection gate line SGS. Note that individual selection gate lines SGS may be connected to the gates of the selection transistors ST2 of the string units SU0 to SU3, respectively. The selection transistors ST1 and ST2 are used to select the string units SU in various operations.

The control gates of the memory cell transistors MT0 to MT7 included in the block BLKn are connected to the word lines WL0 to WL7, respectively. Each of the word lines WL0 to WL7 is independently controlled by the row decoder 18.

Each of the bit lines BL0, BL1, BL2, . . . , BLm (m is a natural number that is zero or more) is connected to the blocks BLK0 to BLKn, and is connected to one NAND string NS in the string unit SU included in the block BLKn. In other words, each of the bit lines BL0 to BLm is connected to the drains of the selection transistors ST1 of the plurality of NAND strings NS in the same column among the NAND strings NS arranged in a matrix in the block BLKn. A source line SL is connected to the blocks BLK0 to BLKn. That is, the source line SL is connected to the sources of the selection transistors ST2 included in the block BLKn.

In short, the string unit SU includes a plurality of NAND strings NS connected to different bit lines BL and connected to the same selection gate line SGD. In addition, the block BLKn includes a plurality of string units SU sharing the word line WL. Further, the memory cell array 11 includes a plurality of blocks BLK0 to BLKn sharing the bit lines BL.

The block BLKn is, for example, a unit of erasing data. In other words, the data stored in the memory cell transistor MT included in the block BLKn is collectively erased. Data in the plurality of blocks is sequentially erased one block at a time. In addition, data in the plurality of blocks is erased simultaneously in parallel. Note that the data may be erased in units of string units SU, or may be erased in units less than the string units SU.

A plurality of memory cell transistors MT sharing the word line WL in one string unit SU is referred to as a cell unit CU. A collection of 1-bit data stored in each of the memory cell transistors MT included in the cell unit CU is referred to as a page. The storage capacity of the cell unit CU changes according to the number of bits of data stored in the memory cell transistor MT. For example, the cell unit CU stores 1-page data in a case where each memory cell transistor MT stores 1-bit data, stores 2-page data in a case where 2-bit data is stored, and stores 3-page data in a case where 3-bit data is stored.

The write operation and the read operation for the cell unit CU are performed in units of pages. In other words, the read operation and the write operation are collectively performed for the plurality of memory cell transistors MT connected to one word line WL disposed in one string unit SU.

Note that the number of string units included in the block BLKn is not limited to SU0 to SU3, and can be arbitrarily set. In addition, the number of NAND strings NS included in the string unit SU and the number of memory cell transistors and selection transistors included in the NAND strings NS can be arbitrarily set. Furthermore, the memory cell transistor MT may be a metal-oxide-nitride-oxide-silicon (MONOS) type using an insulating film as a charge storage layer, or may be a floating gate (FG) type using a conductive layer as a charge storage layer.

### 1.2 Structure of Semiconductor Memory Device

An example of a structure of the semiconductor memory device 10 according to the first embodiment will be described. In the drawings referred to below, the X direction corresponds to the extending direction of the word lines WL, the Y direction corresponds to the extending direction of the bit lines BL, and the Z direction corresponds to a direction orthogonal to the surface of the semiconductor substrate included in the semiconductor memory device 10. In the plan view, hatching is appropriately added for easy viewing of the drawing. The hatching added to the plan view is not necessarily related to a material or a characteristic of the component to which the hatching is added. In each of the plan view and the cross-sectional view, illustration of a wiring, a contact, an interlayer insulating film, and the like is appropriately omitted in order to make the drawing easy to see.

### 1.2.1 Planar Layout of Semiconductor Memory Device

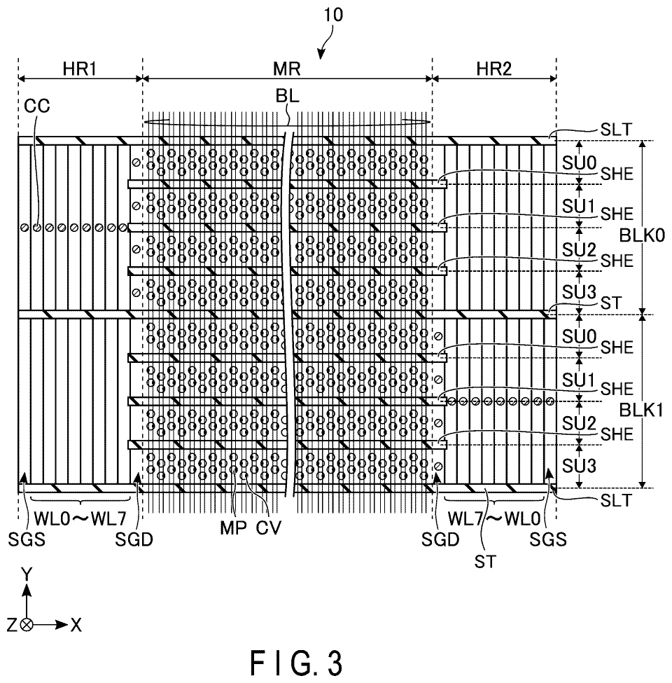

An example of a planar layout of the semiconductor memory device 10 according to the first embodiment will be described with reference to FIG. 3. FIG. 3 is a diagram showing a planar layout of the semiconductor memory device 10. FIG. 3 illustrates regions corresponding to the blocks BLK0 and BLK1.

As illustrated in FIG. 3, the semiconductor memory device 10 includes a plurality of slits SLT and SHE, a plurality of memory pillars MP, a plurality of bit lines BL, and a plurality of contacts CC and CV.

The plurality of slits SLT and SHE are arranged in the Y direction. For example, three slits SHE are arranged between the slit SLT and another slit SLT. Each of the slits SLT and SHE extends along the X direction. Each slit SLT crosses a memory region MR and hookup regions (or staircase regions) HR1 and HR2. Each slit SHE crosses the memory region MR and the selection gate line SGD in the hookup regions HR1 and HR2. In other words, each of the slits SLT or SHE divides and insulates the adjacent wiring layers (or the conductive layer) via the slit SLT or SHE. Specifically, each slit SLT divides and insulates a plurality of wiring layers corresponding to the word lines WL0 to WL7 and the selection gate lines SGD and SGS. Each slit SHE divides and insulates the plurality of wiring layers corresponding to the word lines WL0 to WL7 and the selection gate line SGD.

Each memory pillar MP functions as, for example, one NAND string NS. The plurality of memory pillars MP is arranged in, for example, four rows in a staggered manner in a region between the adjacent slits SLT or SHE in the memory region MR. In this example, each of the regions divided by the slits SLT or SHE corresponds to one string unit SU. Note that the number and arrangement of the memory pillars MP between the adjacent slits SLT or SHE can be appropriately changed.

The plurality of bit lines BL are arranged in the X direction. Each bit line BL extends in the Y direction. Each bit line BL overlaps at least one memory pillar MP for each string unit SU. In this example, two bit lines BL overlap one memory pillar MP. The contact CV is provided between one bit line BL among the plurality of bit lines BL overlapping the memory pillar MP and the memory pillar MP. Each memory pillar MP is connected to the associated bit line BL via the contact CV.

In each of the hookup regions HR1 and HR2, each of the selection gate line SGS, the word lines WL0 to WL7, and the selection gate line SGD has a portion that does not overlap the upper wiring layer (or the conductive layer). The shape of the portion not overlapping with the upper wiring layer is referred to as terrace, step, rimstone, or the like. Hereinafter, in the present specification, a portion not overlapping the upper wiring layer is referred to as a terrace portion. Specifically, terrace portions are provided between the selection gate line SGS and the word line WL0, between the word line WL0 and the word line WL1, between the word line WL1 and the word line WL2, between the word line WL2 and the word line WL3, between the word line WL3 and the word line WL4, between the word line WL4 and the word line WL5, between the word line WL5 and the word line WL6, between the word line WL6 and the word line WL7, and between the word line WL7 and the selection gate line SGD, respectively.

Each of the plurality of contacts CC is used for connection between each of the word lines WL0 to WL7 and the selection gate lines SGS and SGD and the row decoder 18. In addition, each contact CC is arranged on a terrace portion of each of the word lines WL0 to WL7 and the selection gate lines SGS and SGD. Here, an example in which the contacts CC on the terrace portion of the word lines WL0 to WL7 and the selection gate line SGS are arranged in a line in the X direction has been described, but the contacts CC may be arranged to be shifted from each other in the Y direction.

For example, the contact CC associated with the block BLK0 is arranged in the hookup region HR1, and the contact CC associated with the block BLK1 is arranged in the hookup region HR2. In other words, for example, the even-numbered blocks BLK are connected to the row decoder 18 via the contact CC in the hookup region HR1. The odd-numbered blocks BLK are connected to the row decoder 18 via the contact CC in the hookup region HR2.

In the planar layout of the semiconductor memory device 10, the memory region MR and the hookup regions HR1 and HR2 described above are repeatedly arranged in the Y direction. Note that the arrangement of the contact CC with respect to each block BLK is not limited to the above-described layout. For example, in a case where one hookup region HR is omitted, the contacts CC corresponding to the respective blocks BLK are collectively arranged in the hookup region HR on one side in contact with the memory region MR. In addition, the contacts CC may be arranged on both sides of the hookup regions HR1 and HR2, and a voltage may be applied from both sides of each block BLK. The hookup region HR may be disposed so as to be sandwiched by the memory regions MR.

### 1.2.2 Cross-Sectional Structure of Semiconductor Memory Device

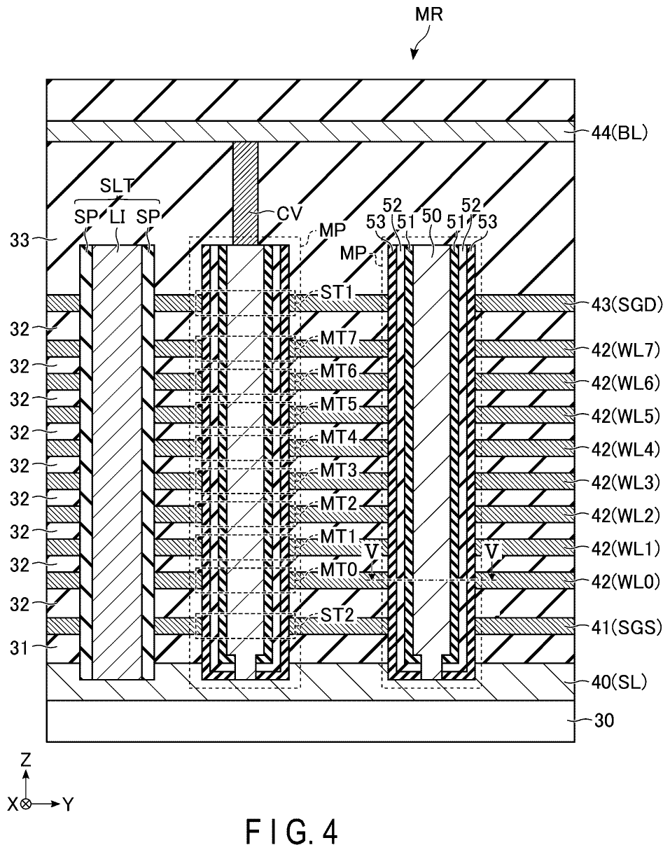

An example of a cross-sectional structure of the memory region MR in the semiconductor memory device 10 according to the first embodiment will be described with reference to FIG. 4. FIG. 4 is a diagram for explaining a cross-sectional structure of the memory region MR in the semiconductor memory device 10. FIG. 4 illustrates a cross section along the Y direction including the memory pillar MP and the slit SLT. Although the memory pillar MP in the semiconductor memory device 10 according to the first embodiment has three layers of memory pillars, FIG. 4 illustrates a case where the memory pillar MP includes one layer to make it easier to understand the structure of the memory pillar MP and its surroundings. The structure of the three-layer memory pillar and the word lines around the memory pillar of the semiconductor memory device 10 will be described later.

The memory region MR includes a semiconductor substrate 30, insulating layers 31 to 33, conductive layers 40 to 44, a memory pillar MP, a contact CV, and a slit SLT.

The conductive layer 40 is provided on the semiconductor substrate 30. The conductive layer 40 is formed in, for example, a plate shape extending along the XY plane and is used as the source line SL. The conductive layer 40 includes, for example, polysilicon doped with phosphorus.

On the conductive layer 40, the insulating layer 31 is provided. On the insulating layer 31, a conductive layer 41 is provided. The conductive layer 41 is formed in, for example, a plate shape extending along the XY plane and is used as the selection gate line SGS. The conductive layer 41 includes, for example, tungsten or polysilicon doped with phosphorus. The selection gate line SGS may include a plurality of conductive layers 41. In a case where the selection gate line SGS includes the plurality of conductive layers 41, the plurality of conductive layers 41 may include different conductors.

On the conductive layer 41, insulating layers 32 and conductive layers 42 are alternately stacked. Each of the plurality of conductive layers 42 is formed in, for example, a plate shape extending along the XY plane. The plurality of conductive layers 42 are used as the word lines WL0 to WL7 in order from the conductive layer 40 side. The conductive layers 42 contain, for example, tungsten. The insulating layers 32 are, for example, oxide layers containing silicon oxide (SiO₂).

On the uppermost insulating layer 32, a conductive layer 43 is provided. The conductive layer 43 is formed in a plate shape extending along the XY plane, for example, and is used as the selection gate line SGD. The selection gate line SGD may include a plurality of conductive layers 43. The conductive layers 43 contain, for example, tungsten.

On the conductive layer 43, the insulating layer 33 is provided. On the insulating layer 33, conductive layers 44 is provided. The conductive layers 44 are formed in a line shape extending in the Y direction, for example, and are used as the bit lines BL. In a region (not illustrated), the plurality of conductive layers 44 are arranged in the X direction. The conductive layers 44 contain, for example, copper.

Each memory pillar MP extends along the Z direction. Each memory pillar MP penetrates the insulating layers 31 and 32 and the conductive layers 41 to 43. A lower portion of the memory pillar MP is in contact with the conductive layer 40. An upper portion of the memory pillar MP reaches the insulating layer 33.

Each memory pillar MP includes, for example, a semiconductor layer 50, a tunnel insulating layer (also referred to as a tunnel insulating film) 51, a charge storage layer (for example, an insulating layer) 52, and a block insulating layer 53.

The semiconductor layer 50 extends along the Z direction. For example, a lower end of the semiconductor layer 50 is in contact with the conductive layer 40. An upper end of the semiconductor layer 50 is included in a layer including the insulating layer 33. The tunnel insulating layer 51 is disposed on a side surface of the semiconductor layer 50. The charge storage layer 52 is disposed on a side surface of the tunnel insulating layer 51. The block insulating layer 53 is disposed on a side surface of the charge storage layer 52. Note that the memory pillar MP may have a structure in which a core insulating layer is provided inside the semiconductor layer 50.

A portion where the memory pillar MP intersects the conductive layer 41 (that is, the selection gate line SGS) functions as the selection transistor ST2. Portions where the memory pillars MP intersect the plurality of conductive layers 42 (that is, the word lines WL) function as memory cell transistors MT0 to MT7, respectively. A portion where the memory pillar MP intersects the conductive layer 43 (that is, the selection gate line SGD) functions as the selection transistor ST1.

The semiconductor layer 50 functions as a channel layer of each of the memory cell transistors MT0 to MT7 and the selection transistors ST1 and ST2. A current path of the NAND string NS is formed inside the semiconductor layer 50. The charge storage layer 52 functions as a layer that stores charges of the memory cell transistor MT.

A columnar contact CV is provided on the semiconductor layer 50 of each memory pillar MP. In the illustrated region, the contact CV corresponding to one memory pillar MP of the two memory pillars MP is illustrated. The contact CV is connected in a region (not illustrated) to the memory pillar MP to which the contact CV is not connected in the region. One conductive layer 44 (that is, the bit line BL) is in contact with the contact CV.

The slit SLT includes, for example, a spacer SP and a contact LI. The slit SLT is formed in a plate shape at least partially extending along the XZ plane, and divides the insulating layers 31 and 32 and the conductive layers 41 to 43. A lower end of the slit SLT is in contact with the conductive layer 40, for example. AN upper end of the slit SLT is included in a layer including the insulating layer 33. In the slit SLT, at least a part of the contact LI extends in the X direction. The spacer SP is provided on the side surface of the contact LI. The contact LI and the plurality of conductive layers 41 to 43 are separated and insulated by the spacer SP.

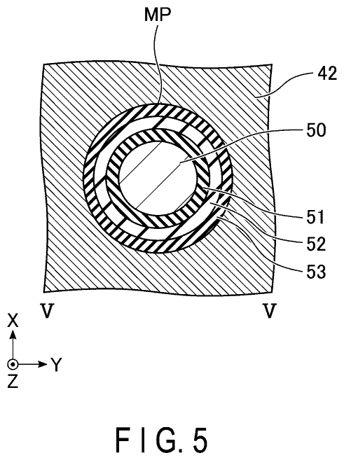

Next, a cross-sectional structure of the memory pillar MP provided in the memory region MR will be described. FIG. 5 illustrates a cross section taken along line V-V in FIG. 4, and illustrates a cross section of the memory pillar MP in a layer parallel to the surface of the semiconductor substrate 30 and including the conductive layer 42.

As described above, the memory pillar MP includes, for example, the semiconductor layer 50, the tunnel insulating layer 51, the charge storage layer 52, and the block insulating layer 53. Specifically, the semiconductor layer 50 is provided, for example, at the central portion of the memory pillar MP. The tunnel insulating layer 51 surrounds the side surface of the semiconductor layer 50. The charge storage layer 52 surrounds the side surface of the tunnel insulating layer 51. The block insulating layer 53 surrounds the side surface of the charge storage layer 52. The conductive layer 42 surrounds the side surface of the block insulating layer 53. Note that the memory pillar MP may have a structure in which a core insulating layer is provided inside the semiconductor layer 50.

The tunnel insulating layer 51 functions as a potential barrier in a case where a charge is injected from the semiconductor layer 50 into the charge storage layer 52 or in a case where a charge stored in the charge storage layer 52 diffuses into the semiconductor layer 50. The tunnel insulating layer 51 contains, for example, silicon oxide (SiO₂).

The charge storage layer 52 has a function of storing charges injected from the semiconductor layer 50 in the memory cell transistors MT0 to MT7. The charge storage layer 52 includes, for example, silicon nitride (SiN).

The block insulating layer 53 prevents the charges stored in the charge storage layer 52 from diffusing to the conductive layer 42 (the word line WL). The block insulating layer 53 includes, for example, an aluminum oxide layer, a silicon oxide layer, and a silicon nitride layer.

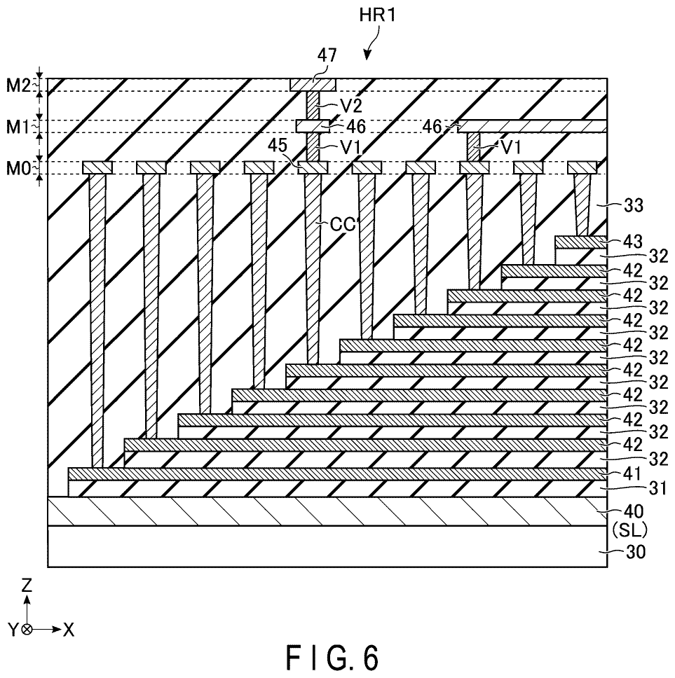

Next, an example of a cross-sectional structure of the hookup region HR1 in the semiconductor memory device 10 according to the first embodiment will be described with reference to FIG. 6. FIG. 6 is a diagram for explaining a cross-sectional structure of the hookup region HR1 in the semiconductor memory device 10. FIG. 6 illustrates a cross section along the X direction of a region corresponding to the hookup region HR1 and the even-numbered block BLK in FIG. 4.

In the hookup region HR1, the respective ends of the selection gate line SGS (conductive layer 41), the word lines WL0 to WL7 (conductive layer 42), and the selection gate line SGD (conductive layer 43) are provided in a stepwise manner. In the hookup region HR1, for example, contacts CC, contacts V1 and V2, and conductive layers 45, 46, and 47 are provided.

Specifically, the conductive layer 41 has a terrace portion that does not overlap the upper conductive layers 42 and 43 in the Z direction. Each of the conductive layers 42 has a terrace portion that does not overlap the upper conductive layers 42 and 43 in the Z direction. The conductive layer 43 has a terrace portion in the Z direction. The plurality of contacts CC are provided on the respective terrace portions of the conductive layers 41 to 43.

For example, the conductive layers 45 are provided on each contact CC. The conductive layers 45 are included in a wiring layer M0. On the conductive layer 45, the contact V1 is provided. On the contact V1, a conductive layer 46 is provided. The conductive layer 46 is included in a wiring layer M1. On the conductive layer 46, the contact V2 is provided. On the contact V2, a conductive layer 47 is provided. The conductive layer 47 is included in a wiring layer M2.

Note that FIG. 6 illustrates only a set of the contacts V1 and V2 and the conductive layers 46 and 47 provided in the conductive layer 45 corresponding to the word line WL3. To the other conductive layers 45, in unillustrated regions, a set of contacts V1 and V2 and conductive layers 46 and 47 is connected.

In addition, the structure in the region corresponding to the hookup region HR1 and the odd-numbered block BLK is similar to the structure in which the contact CC is omitted from the structure illustrated in FIG. 6. In addition, the structure in the hookup region HR2 and the region corresponding to the odd-numbered block BLK is similar to a structure obtained by inverting the structure illustrated in FIG. 6 with the YZ plane as a symmetry plane.

### 1.2.3 Structure of Memory Pillars and Word Lines

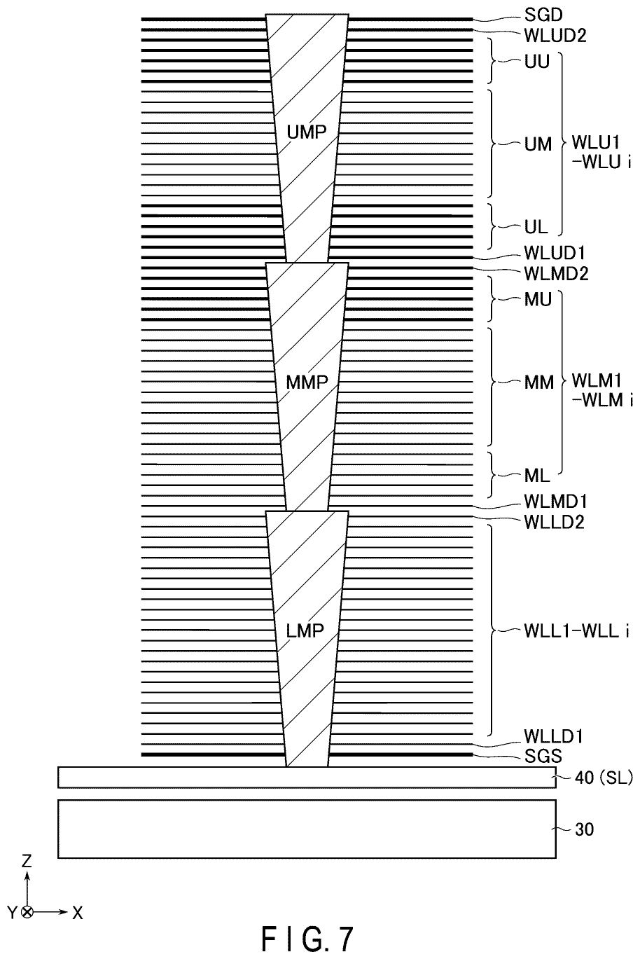

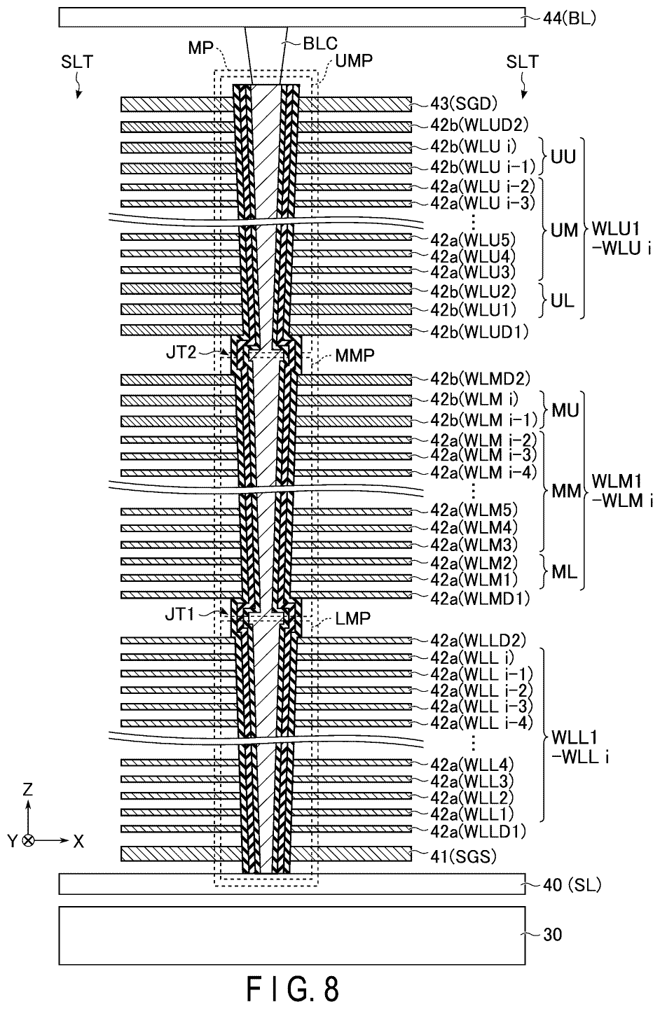

Next, the structures of the memory pillar MP and the word lines WL in the semiconductor memory device 10 according to the first embodiment will be described in detail with reference to FIGS. 7 and 8. FIG. 7 is a cross-sectional view showing an outline of structures of the memory pillars and the word lines in the semiconductor memory device 10. FIG. 8 is a cross-sectional view showing details of the structures of the memory pillars and the word lines in the semiconductor memory device 10.

In FIG. 4 described above, in order to describe the cross-sectional structure of the memory region MR, the memory pillar MP has been simplified to one. However, in the semiconductor memory device 10 according to the present embodiment, as illustrated in FIGS. 7 and 8, the memory pillar MP can be structurally divided into three memory pillars, that is, a lower pillar LMP, a middle pillar MMP, and an upper pillar UMP.

In the cross section of the XZ plane or the YZ plane, the cross section of each of the lower pillar LMP, the middle pillar MMP, and the upper pillar UMP has a tapered shape that narrows from the upper end toward the lower end, that is, from the bit line BL side toward the source line SL. The cross section of the upper end of each of the lower pillar LMP, the middle pillar MMP, and the upper pillar UMP is thicker than the cross section of the lower end of each thereof.

The diameter of the lower end of the middle pillar MMP along the XY plane is larger than the diameter of the upper end of the lower pillar LMP along the XY plane. A boundary between the lower end of the middle pillar MMP and the upper end of the lower pillar LMP is a boundary between the middle pillar MMP and the lower pillar LMP. The diameter of the lower end of the upper pillar UMP along the XY plane is larger than the diameter of the upper end of the middle pillar MMP along the XY plane. A boundary between the lower end of the upper pillar UMP and the upper end of the middle pillar MMP is the boundary between the upper pillar UMP and the middle pillar MMP.

The lower pillar LMP, the middle pillar MMP, and the upper pillar UMP are stacked on the source line SL in the Z direction. A plurality of word lines stacked in the Z direction is provided around the lower pillar LMP, the middle pillar MMP, and the upper pillar UMP.

First, an outline of the structures of the memory pillars MP and the word lines WL in the semiconductor memory device 10 according to the first embodiment will be described with reference to FIG. 7.

As illustrated in FIG. 7, the source line SL is provided above semiconductor substrate 30. The selection gate line SGS is provided above the source line SL. A dummy word line WLLD1 is provided above the selection gate line SGS. Above the dummy word line WLLD1, a plurality of word lines WLL1, WLL2, . . . , WLLi (i is an integer that is one or more) are stacked. Furthermore, a dummy word line WLLD2 is provided above the word line WLLi.

Above the dummy word line WLLD2, a dummy word line WLMD1 is provided. Above the dummy word line WLMD1, a plurality of word lines WLM1, WLM2, WLMi are stacked. Furthermore, above the word line WLMi, a dummy word line WLMD2 is provided.

The plurality of word lines WLM1 to WLMi are divided into lower word lines ML, middle word lines MM, and upper word lines MU from the side of the dummy word line WLMD1 (or the source line SL). The lower word lines ML include a plurality of word lines stacked immediately (or directly) above the dummy word line WLMD1. The middle word lines MM include a plurality of word lines stacked immediately above the lower word lines ML. The upper word lines MU include a plurality of word lines stacked immediately above the middle word lines MM.

The upper word lines MU are disposed in the vicinity of the upper end of the middle pillar MMP. The lower word lines ML are disposed in the vicinity of the lower end of the middle pillar MMP. The middle word lines MM are disposed between the upper word lines MU and the lower word lines ML.

Above the dummy word line WLMD2, a dummy word line WLUD1 is provided. Above the dummy word line WLUD1, a plurality of word lines WLU1, WLU2, WLUi are stacked. Above the word line WLUi, a dummy word line WLUD2 is provided. Further, the selection gate line SGD is provided above the dummy word line WLUD2.

The plurality of word lines WLU1 to WLUi are divided into lower word lines UL, middle word lines UM, and upper word lines UU from the side of the dummy word line WLUD1 (or the source line SL). The lower word lines UL include a plurality of word lines stacked immediately above the dummy word line WLUD1. The middle word lines UM include a plurality of word lines stacked immediately above the lower word lines UL. The upper word lines UU include a plurality of word lines stacked immediately above the middle word lines UM.

The upper word lines UU are disposed in the vicinity of the upper end of the upper pillar UMP. The lower word lines UL are disposed in the vicinity of the boundary between the upper pillar UMP and the middle pillar MMP. The middle word lines UM are disposed between the upper word lines UU and the lower word lines UL.

The plurality of word lines WLL1 to WLLi, WLM1 to WLMi, and WLU1 to WLUi are electrically connected to the row decoder 18 via the contacts CC, other contacts, and conductive layers, respectively. The selection gate lines SGD and SGS are electrically connected to the row decoder 18 via the contacts CC, other contacts, and conductive layers, respectively. The dummy word lines are not electrically connected to the row decoder 18.

Above the source line SL, the lower pillar LMP, the middle pillar MMP, and the upper pillar UMP extending in the Z direction are sequentially stacked in the Z direction. Specifically, the lower pillar LMP is provided on the source line SL. The middle pillar MMP is provided on the lower pillar LMP in the Z direction. The upper pillar UMP is provided on the middle pillar MMP in the Z direction. In other words, the lower end of the lower pillar LMP is connected to the source line SL, and the lower end of the middle pillar MMP is connected to the upper end of the lower pillar LMP. Further, the lower end of the upper pillar UMP is connected to the upper end of the middle pillar MMP.

The lower pillar LMP penetrates, in the Z direction, the selection gate line SGS, the dummy word line WLLD1, the plurality of word lines WLL1 to WLLi, and the dummy word line WLLD2 stacked in the Z direction. In other words, the selection gate line SGS, the dummy word line WLLD1, the plurality of word lines WLL1 to WLLi, and the dummy word line WLLD2 stacked in the Z direction are disposed around, in the X direction and the Y direction, the lower pillar LMP extending in the Z direction.

The middle pillar MMP penetrates, in the Z direction, the dummy word line WLMD1, the plurality of word lines WLM1 to WLMi, and the dummy word line WLMD2 stacked in the Z direction. In other words, the dummy word line WLMD1, the plurality of word lines WLM1 to WLMi, and the dummy word line WLMD2 stacked in the Z direction are disposed around, in the X direction and the Y direction, the middle pillar MMP extending in the Z direction.

The upper pillar UMP penetrates, in the Z direction, the dummy word line WLUD1, the plurality of word lines WLU1 to WLUi, the dummy word line WLUD2, and the selection gate line SGD stacked in the Z direction. In other words, the dummy word line WLUD1, the plurality of word lines WLU1 to WLUi, the dummy word line WLUD2, and the selection gate line SGD stacked in the Z direction are disposed around, in the X direction and the Y direction, the upper pillar UMP extending in the Z direction.

Hereinafter, the film thicknesses of the word lines WL provided around the lower pillar LMP, the middle pillar MMP, and the upper pillar UMP will be described.

In the word lines WLU1 to WLUi and the word lines WLM1 to WLMi provided around the upper pillar UMP and the middle pillar MMP, the film thickness of each of the upper word lines UU, the lower word lines UL, and the upper word lines MU is thicker than the film thickness of each of the middle word lines UM. The film thickness of each of the upper word lines UU, the lower word lines UL, and the upper word lines MU is substantially equal, that is, substantially the same. The film thickness of each of the middle word lines MM and the lower word lines ML is substantially equal to, that is, substantially the same as the film thickness of each of the middle word lines UM.

The film thickness of each of the dummy word lines WLUD1, WLUD2, and WLMD2 is thicker than the film thickness of each of the middle word lines UM. The film thickness of each of the dummy word lines WLUD1, WLUD2, and WLMD2 is substantially equal to, that is, substantially the same as the film thickness of each of the upper word lines UU, the lower word lines UL, and the upper word lines MU.

The film thickness of the selection gate line SGD is thicker than the film thickness of each of the upper word lines UU and the lower word lines UL. In addition, the film thickness of the dummy word line WLMD1 is substantially equal to, that is, substantially the same as the film thickness of each of the middle word lines UM.

The film thickness of each of the word lines WLL1 to WLLi provided around the lower pillar LMP is substantially equal to, that is, substantially the same as the film thickness of each of the middle word lines UM. Similarly, the film thickness of each of the dummy word lines WLLD1 and WLLD2 is substantially equal to, that is, substantially the same as the film thickness of each of the middle word lines UM. The film thickness of the selection gate line SGS is thicker than the film thickness of each of the upper word lines UU and the lower word lines UL.

Although the case where the three memory pillars, that is, the lower pillar LMP, the middle pillar MMP, and the upper pillar UMP are stacked has been described above, the present invention is not limited thereto, and two or four or more memory pillars may be stacked. In addition, the case where i word lines are provided around each of the lower pillar LMP, the middle pillar MMP, and the upper pillar UMP has been described, but the present invention is not limited thereto. The number of word lines provided around each of the lower pillar LMP, the middle pillar MMP, and the upper pillar UMP may be different.

Next, the structures of the memory pillars MP and the word lines WL in the semiconductor memory device 10 according to the first embodiment will be described in detail with reference to FIG. 8. In FIG. 8, the interlayer insulating layers between the conductive layers are omitted.

As illustrated in FIG. 8, the conductive layer 40 is provided above the semiconductor substrate 30 via an insulating layer. The conductive layer 40 is formed in a flat plate shape along the XY plane. The conductive layer 40 functions as the source line SL. The main surface of the semiconductor substrate 30 or the conductive layer 40 corresponds to the XY plane.

On the conductive layer 40, a plurality of slits SLT along the YZ plane are arranged in the X direction. A structure between adjacent slits SLT on the conductive layer 40 corresponds to, for example, one string unit SU. Specifically, on the conductive layer 40 and between the adjacent slits SLT, the conductive layer 41, the plurality of conductive layers 42a, the plurality of conductive layers 42b, the conductive layer 43, and the conductive layer 44 are provided in this order from the lower side. Among these conductive layers, conductive layers adjacent to each other in the Z direction are stacked with an interlayer insulating film interposed therebetween. Each of the conductive layers 41, 42a, 42b, 43, and 44 is formed in a flat plate shape along the XY plane.

The plurality of memory pillars MP (including the pillars LMP, MMP, and UMP) are arranged in a staggered manner in the Y direction, for example (not illustrated). Each of the memory pillars MP functions as one NAND string NS. Each memory pillar MP, that is, the stacked lower pillar LMP, middle pillar MMP, and upper pillar UMP is provided so as to penetrate the conductive layers 41, 42a, 42b, and 43 so as to reach the upper surface of the conductive layer 43 from the upper surface of the conductive layer 40.

The lower pillar LMP is provided on the conductive layer 40. A joint portion JT1 is provided between the lower pillar LMP and the middle pillar MMP. The middle pillar MMP is joined to the lower pillar LMP via the joint portion JT1. A joint portion JT2 is provided between the middle pillar MMP and the upper pillar UMP. The upper pillar UMP is joined to the middle pillar MMP via the joint portion JT2.

The conductive layer 41 provided around the lower pillar LMP functions as the selection gate line SGS. The plurality of conductive layers 42a around the lower pillar LMP function as the dummy word line WLLD1, the word lines WLL1 to WLLi, and the dummy word line WLLD2 in order from the lower layer.

The plurality of conductive layers 42a provided around the middle pillar MMP function as the dummy word line WLMD1 and the word lines WLM1 to WLMi−2, respectively, in order from the lower layer. The plurality of conductive layers 42b around the middle pillar MMP function as the word lines WLMi−1 and WLMi and the dummy word line WLMD2 in order from the lower layer.

The plurality of conductive layers 42b provided around the upper pillar UMP function as the dummy word line WLUD1 and the word lines WLU1 and WLU2 in order from the lower layer. The plurality of conductive layers 42a around the upper pillar UMP function as the word lines WLU3 to WLUi−2, respectively, in order from the lower layer, and the plurality of conductive layers 42b function as the word lines WLUi−1, WLUi, and the dummy word line WLUD2, respectively. Further, the conductive layer 43 around the upper pillar UMP functions as the selection gate line SGD.

A portion where the lower pillar LMP intersects the selection gate line SGS functions as the selection transistor ST2. Portions where the lower pillar LMP intersects the dummy word lines WLLD1 and WLLD2 function as dummy transistors, respectively. Each dummy transistor is a memory cell in which data is not stored. Portions where the lower pillar LMP intersects the word lines WLL1 to WLLi function as memory cell transistors, respectively. Each memory cell transistor is a memory cell in which data is stored or data can be stored.

Portions where the middle pillar MMP intersects the dummy word lines WLMD1 and WLMD2 function as dummy transistors, respectively. Each dummy transistor is a transistor in which data is not stored. Portions where the middle pillar MMP intersects the word lines WLM1 to WLMi function as memory cell transistors, respectively. Each memory cell transistor is a memory cell in which data is stored or data can be stored.

Portions where the upper pillar UMP intersects the dummy word lines WLUD1 and WLUD2 function as dummy transistors, respectively. Each dummy transistor is a transistor in which data is not stored. Portions where the upper pillar UMP intersects the word lines WLU1 to WLUi function as memory cell transistors, respectively. Each memory cell transistor is a memory cell in which data is stored or data can be stored. Further, a portion where the upper pillar UMP intersects the selection gate line SGD functions as the selection transistor ST1.

The conductive layer 44 is provided above the upper pillar UMP via an interlayer insulating film. The conductive layer 44 is formed in a line shape extending in the X direction and functions as a bit line (or a wiring layer) BL. The plurality of conductive layers 44 is arranged in the Y direction (not illustrated). Each of the conductive layers 44 is electrically connected to one memory pillar MP corresponding to each string unit SU. Specifically, in each string unit SU, a contact BLC is provided on the semiconductor layer 50 in each memory pillar MP, and one conductive layer 44 is provided on the contact BLC. The contact BLC includes a conductive layer, for example, tungsten.

In addition, the numbers of the word lines WL, the dummy word lines, and the selection gate lines SGD and SGS are changed according to the numbers of the memory cell transistors MT, the dummy transistors, and the selection transistors ST1 and ST2, respectively. The selection gate line SGS may include a plurality of conductive layers provided in a plurality of layers. The selection gate line SGD may include a plurality of conductive layers provided in a plurality of layers.

In the above-described structure, as described above, the film thickness of each of the upper word lines UU, the lower word lines UL, and the upper word lines MU is thicker than the film thickness of each of the middle word lines UM. The film thicknesses of the other word lines except the upper word lines UU, the lower word lines UL, and the upper word lines MU are substantially equal to the film thickness of each of the middle word lines UM.

The film thickness of each of the dummy word lines WLUD1, WLUD2, and WLMD2 is thicker than the film thickness of each of the middle word lines UM. The film thicknesses of the other dummy word lines except the dummy word lines WLUD1, WLUD2, and WLMD2 are substantially equal to the film thicknesses of the respective middle word lines UM.

The film thickness of each of the selection gate lines SGD and SGS is thicker than the film thickness of each of the upper word lines UU and the lower word lines UL.

For example, the number of word lines WLL1 to WLLi provided around the lower pillar LMP is several hundred. Similarly, the number of word lines WLM1 to WLMi provided around the middle pillar MMP is several hundred. The number of word lines WLU1 to WLUi provided around the upper pillar UMP is several hundred.

The number of word lines included in the upper word lines UU is, for example, 5 to 30, and preferably 5 to 10. Similarly, the number of word lines included in the lower word lines UL is, for example, 5 to 30, and preferably 5 to 10. The number of word lines included in the upper word lines MU is also 5 to 30, and preferably 5 to 10. In other words, the number of word lines included in the upper word lines UU, the number of word lines included in the lower word lines UL, and the number of word lines included in the upper word lines MU are at least five each.

The film thickness of each of the word lines WLU1 to WLUi is, for example, 20 to 30 nm. Similarly, the film thickness of each of the word lines WLM1 to WLMi is, for example, 20 to 30 nm. The film thickness of each of the word lines WLL1 to WLLi is, for example, 20 to 30 nm. The film thickness of each of the dummy word lines WLUD1, WLUD2, and WLMD1, WLMD2, WLLD1, and WLLD2 is also, for example, 20 to 30 nm.

The film thickness of the word lines thickened in the present embodiment is set to be about 0.5 to 3 nm thicker than the film thickness of the word lines not thickened. For example, in a case where the film thickness of the word lines included in the middle word lines UM is 20 nm, the film thickness of the word lines included in the upper word lines UU is 20.5 to 23 nm. In a case where the film thickness of the word lines included in the middle word lines UM is 25 nm, the film thickness of the word lines included in the upper word lines UU is 25.5 to 28 nm.

Similarly, for example, in a case where the film thickness of the word lines included in the middle word lines UM is 20 nm, the film thickness of the word lines included in the lower word lines UL is 20.5 to 23 nm. In a case where the film thickness of the word lines included in the middle word lines UM is 25 nm, the film thickness of the word lines included in the lower word lines UL is 25.5 to 28 nm.

For example, in a case where the film thickness of the word lines included in the middle word lines UM is 20 nm, the film thickness of the word lines included in the upper word lines MU is 20.5 to 23 nm. In a case where the film thickness of the word lines included in the middle word lines UM is 25 nm, the film thickness of the word lines included in the upper word lines MU is 25.5 to 28 nm.

The film thickness of each of the dummy word lines WLUD1, WLUD2, and WLMD2 is the same. In a case where the film thickness of the word lines included in the middle word lines UM is 20 nm, the film thickness of each of the dummy word lines WLUD1, WLUD2, and WLMD2 is 20.5 to 23 nm. In a case where the film thickness of the word lines included in the middle word lines UM is 25 nm, the film thickness of each of the dummy word lines WLUD1, WLUD2, and WLMD2 is 25.5 to 28 nm.

The film thickness of each of the selection gate lines SGD and SGS is thicker than the film thickness of each of the word lines included in the upper word lines UU, the lower word lines UL, and the upper word lines MU. The film thickness of each of the selection gate lines SGD and SGS is, for example, 30 to 40 nm.

### 1.3 Method for Manufacturing Contacts

Next, a method of manufacturing the contacts CC formed in the hookup region HR1 of the semiconductor memory device 10 according to the first embodiment will be described. The contacts CC are formed on the terrace portion provided at the ends of the word lines WL and the selection gate lines SGD and SGS of the hookup region HR1.

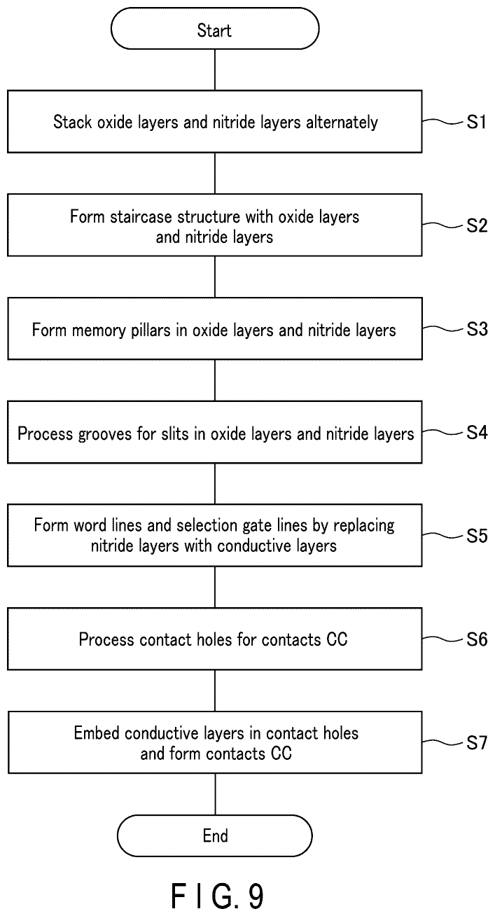

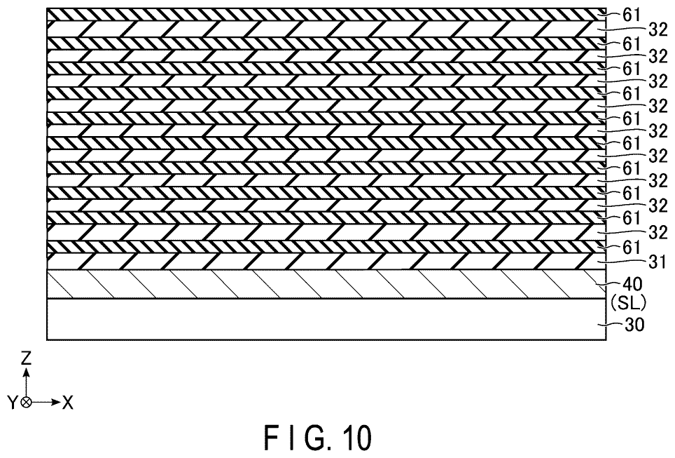

FIG. 9 is a flowchart showing a method of manufacturing the contacts CC in the semiconductor memory device 10 according to the first embodiment. FIGS. 10 to 14 are cross-sectional views showing a method of manufacturing the contacts CC in the semiconductor memory device 10.

First, as illustrated in FIG. 10, an insulating layer, for example, an oxide layer 31 is formed above the semiconductor substrate 30 using, for example, chemical vapor deposition (CVD), and further, insulating layers, for example, oxide layers 32 and nitride layers 61 are alternately stacked (S1). The nitride layers 61 are sacrificial layers to be replaced with conductive layers that constitute word lines and a selection gate line in a replacement step to be described later. In this step, the nitride layers 61 corresponding to the word lines (that is, the upper word lines UU, the lower word lines UL, and the upper word lines MU) to be thickened are formed to be thicker than the other nitride layers. The oxide layers 31 and 32 contain, for example, silicon oxide (SiO₂). The nitride layers 61 contain, for example, silicon nitride (SiN).

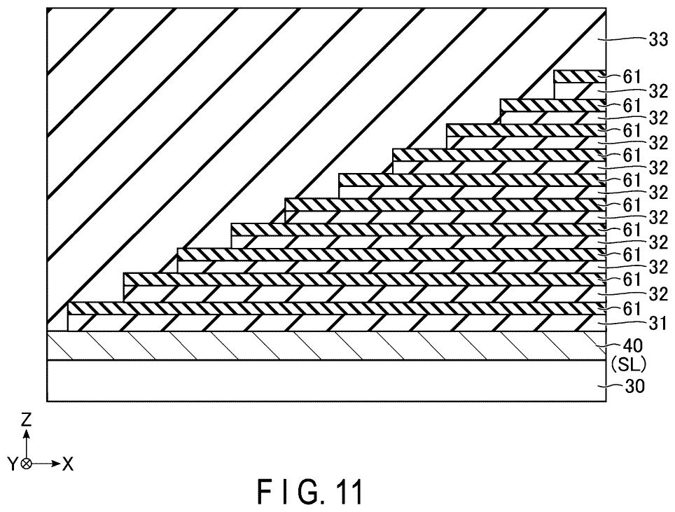

Next, as illustrated in FIG. 11, a staircase structure is formed with the oxide layers 31 and 32 and the nitride layers 61 as illustrated in FIG. 11 by using a slimming method or the like in which reduction of the mask region and anisotropic etching or reactive ion etching (RIE) for example are repeated (S2). In this step, the oxide layers 31 and 32 and the nitride layers 61 are processed stepwise with a set of one oxide layer and one nitride layer as one step. Thereafter, the insulating layer 33 is formed.

Next, unillustrated memory pillars MP (see the MP illustrated in FIG. 3) are formed in the oxide layers 31 and 32 and the nitride layers 61 in the memory region MR (S3). The memory pillars MP are formed so as to penetrate the oxide layers 31 and 32 and the nitride layers 61 of the memory region MR in the Z direction.

Next, for example, grooves for forming unillustrated slits SLT (see the SLTs illustrated in FIG. 3) is processed in the oxide layers 31 and 32 and the nitride layers 61 in the memory region MR using RIE (S4). The grooves are holes along the XZ plane, and the cross sections of the nitride layers 61 are exposed in the groove.

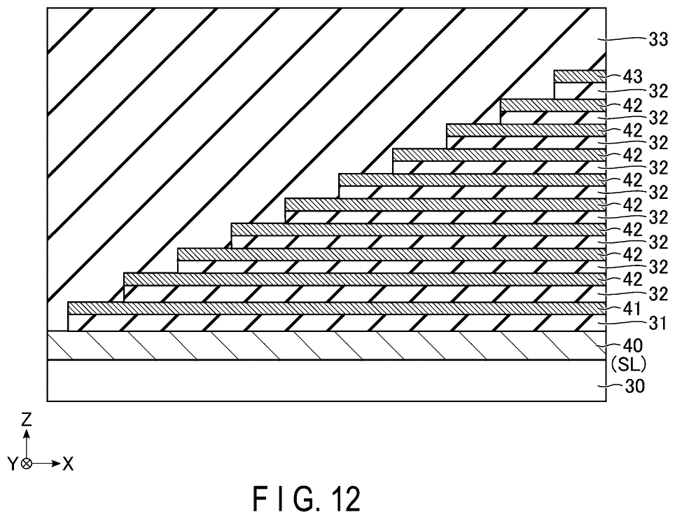

Next, for example, as illustrated in FIG. 12, the word lines WL and the selection gate lines SGS and SGD are formed by replacing the nitride layers 61 with conductive layers in the replacement step (S5). The replacement step is a step of replacing the nitride layers 61 with conductive layers. Specifically, first, the nitride layers 61 are removed via the grooves by wet etching. Subsequently, the conductive layer are formed, by using CVD for example, in the gaps from which the nitride layers 61 have been removed. Thereafter, a process such as etch back is performed to form the conductive layers 42 as the word lines WL, the conductive layer 41 as the selection gate line SGS, and the conductive layer 43 as the selection gate line SGD. The conductive layers 41, 42, and 43 contain tungsten, for example.

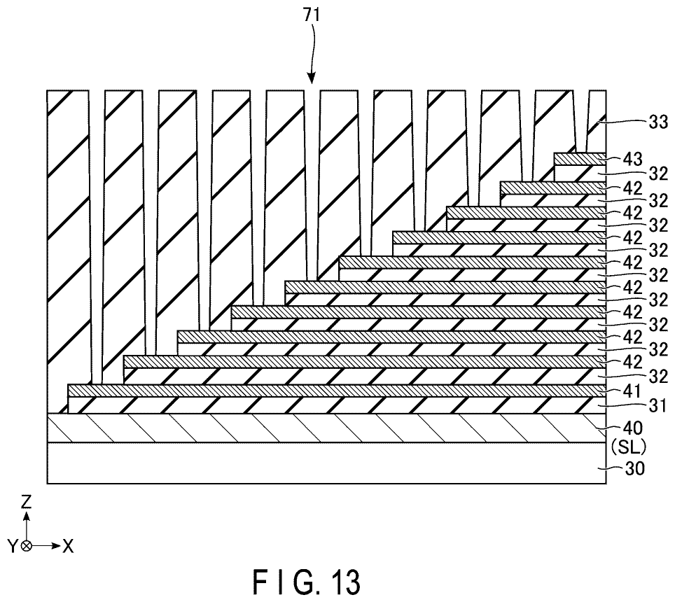

Next, as illustrated in FIG. 13, contact holes 71 for forming the contacts CC in the insulating layer 33 is processed (S6). Specifically, for example, the insulating layer 33 on the terrace portion provided at the ends of the conductive layers 41, 42, and 43 is etched using RIE to form the contact holes 71. Regarding the thickened word lines (that is, the upper word lines UU, the lower word lines UL, and the upper word lines MU), since the film thickness of the word lines WL is formed thick, it can be prevented that the contact hole 71 passes through the target word line WL to reach the word line WL below or to reach the vicinity of the word line WL below at the time of forming the contact holes 71.

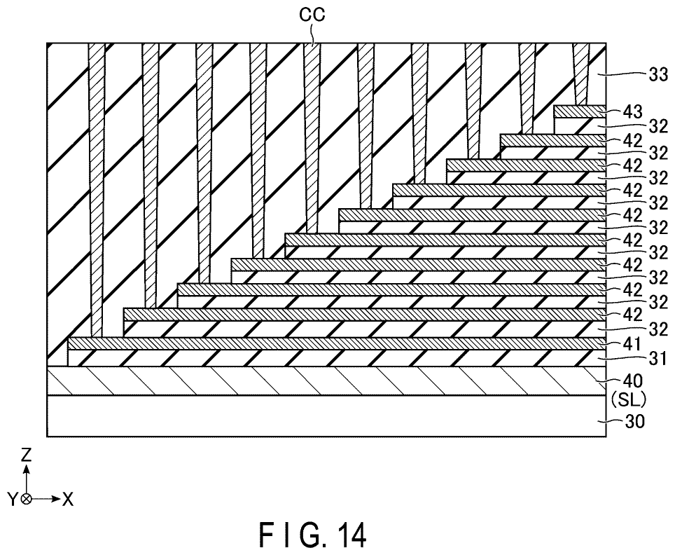

Next, as illustrated in FIG. 14, conductive layers are embedded in the contact holes 71 to form the contacts CC (S7). Specifically, for example, the conductive layers are formed in the contact holes 71 by CVD. Thereafter, the extra conductive layer is removed using, for example, chemical mechanical polishing (CMP) to form the contacts CC. Each contact CC is in contact with the conductive layer 42, 41, or 43 at the terrace portion. Thus, each contact CC is electrically connected to the conductive layer 42, 41, or 43. In this manner, the manufacturing of the contacts CC is completed.

Thereafter, the conductive layers 45, 46, and 47, the contacts V1 and V2, the insulating layer 33, and the like are formed, and the contacts CC are connected to the row decoder 18. As a result, the word lines WL, the selection gate lines SGS and SGD are electrically connected to the row decoder 18 via the contacts CC, the conductive layers 45, 46, and 47, and the contacts V1 and V2.

### 1.4 Effects of First Embodiment

According to the first embodiment, a semiconductor memory device capable of improving operation reliability can be provided.

Hereinafter, effects of the first embodiment will be described.

For example, in the semiconductor memory device, the plurality of word lines are stacked on the substrate in the Z direction, and the row decoder for supplying voltage to the word lines is provided. The memory pillars are provided in the Z direction so as to penetrate through the plurality of word lines. The contacts CC for connecting the word lines to the row decoder is formed at each end of the word lines.

In the formation of the contacts CC, in a case where a contact hole for forming each contacts CC is processed, the contact hole may pass through a target word line to reach a word line below or to reach the vicinity of a word line below. In such a case, in use before shipment or after shipment, a problem such as a short circuit between upper and lower word lines may occur.

According to the first embodiment, among the plurality of stacked word lines WL, the film thicknesses of the word lines of some layers in which the above-described defect is likely to occur, that is, the upper word lines UU and the lower word lines UL around the upper pillar UMP and the upper word lines MU around the middle pillar MMP are thickened. In other words, the film thicknesses of the word lines WL included in the upper word lines UU, the word lines WL included in the lower word lines UL, and the word lines WL included in the upper word lines MU are formed to be thicker than the film thickness of the word lines WL included in the middle word lines UM.

With this configuration, at the time of processing the contact holes, it can be prevented that the contact hole passes through the target word line WL and reaching the word line WL below or reaching the vicinity of the word line WL below, and the occurrence of the above-described problems can be reduced.

As described above, according to the semiconductor memory device 10 of the first embodiment, defects such as short circuits occurring in the upper and lower word lines WL can be reduced, and the reliability of the operation is improved.

### 2. Second Embodiment

A semiconductor memory device according to a second embodiment will be described. In the second embodiment, an example in which the film thickness of the upper word lines UU provided around the upper pillar UMP is formed thick will be described. In the second embodiment, points different from the first embodiment will be mainly described.

### 2.1 Structure of Memory Pillars and Word Lines

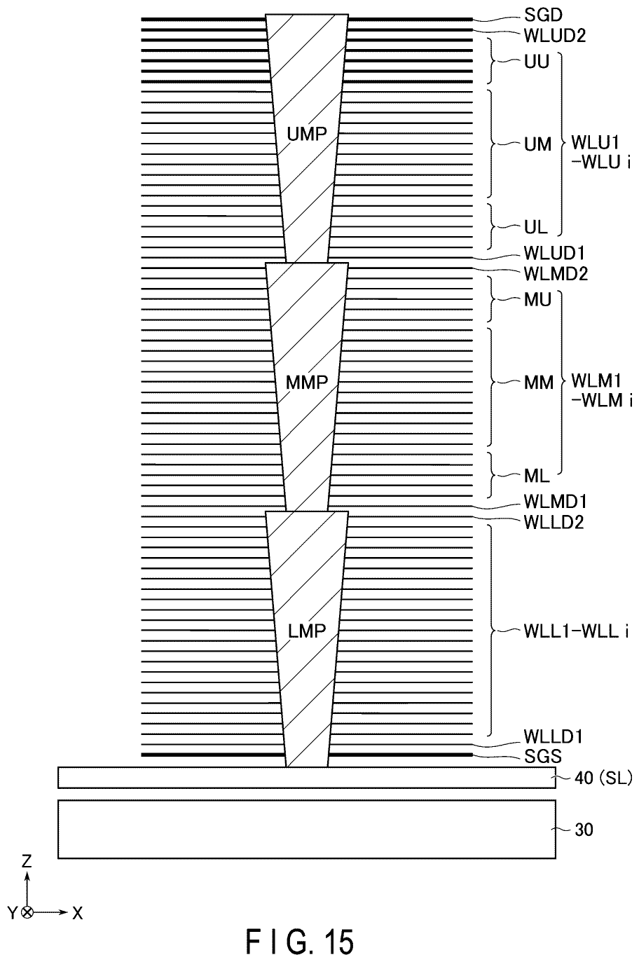

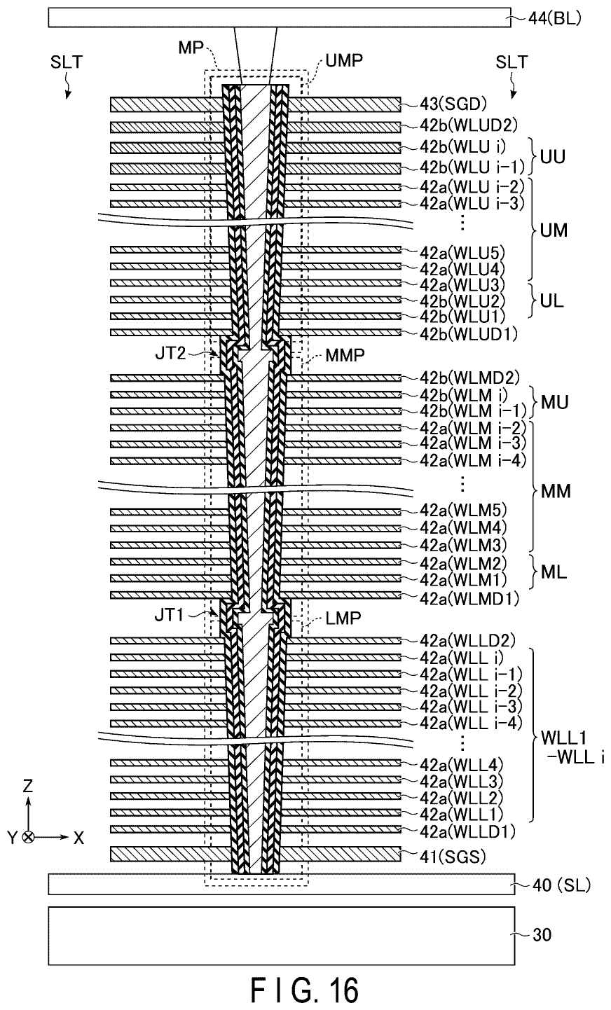

The structures of memory pillars MP and word lines WL in a semiconductor memory device 10 according to the second embodiment will be described with reference to FIGS. 15 and 16. FIG. 15 is a cross-sectional view showing an outline of structures of the memory pillars and the word lines in the semiconductor memory device 10. FIG. 16 is a cross-sectional view showing details of the structures of the memory pillars and the word lines in the semiconductor memory device 10.

Hereinafter, the film thicknesses of the word lines WL provided around the lower pillar LMP, the middle pillar MMP, and the upper pillar UMP will be described.

As illustrated in FIGS. 15 and 16, in word lines WLU1 to WLUi and word lines WLM1 to WLMi provided around the upper pillar UMP and the middle pillar MMP, the film thickness of each of upper word lines UU is thicker than the film thickness of each of middle word lines UM. The film thicknesses of the middle word lines UM, lower word lines UL, upper word lines MU, middle word lines MM, and lower word lines ML are substantially equal, that is, substantially the same.

The film thickness of a dummy word line WLUD2 is thicker than the film thickness of each of the middle word lines UM. The film thickness of the dummy word line WLUD2 is substantially equal to, that is, substantially the same as the film thickness of each of the upper word lines UU. The film thickness of each of dummy word lines WLUD1, WLMD1, and WLMD2 is substantially equal to, that is, substantially the same as the film thickness of each of the middle word lines UM. The film thickness of a selection gate line SGD is thicker than the film thickness of each of the upper word lines UU.

The film thickness of each of the word lines WLL1 to WLLi provided around the lower pillar LMP is substantially equal to, that is, substantially the same as the film thickness of each of the middle word lines UM. Similarly, the film thickness of each of the dummy word lines WLLD1 and WLLD2 is substantially equal to, that is, substantially the same as the film thickness of each of the middle word lines UM. In addition, the film thickness of a selection gate line SGS is thicker than the film thickness of each of the upper word lines UU.

The film thickness of the word lines thickened in the present embodiment is set to be about 0.5 to 3 nm thicker than the film thickness of the word lines not thickened. For example, in a case where the film thickness of the word lines included in the middle word lines UM is 20 nm, the film thickness of the word lines included in the upper word lines UU is 20.5 to 23 nm. In a case where the film thickness of the word lines included in the middle word lines UM is 25 nm, the film thickness of the word lines included in the upper word lines UU is 25.5 to 28 nm.

The same applies to the film thickness of the dummy word line WLUD2. In a case where the film thickness of the word lines included in the middle word lines UM is 20 nm, the film thickness of the dummy word line WLUD2 is 20.5 to 23 nm. In a case where the film thickness of the word lines included in the middle word lines UM is 25 nm, the film thickness of the dummy word line WLUD2 is 25.5 to 28 nm.

### 2.2. Modifications

A first modification and a second modification of the second embodiment will be described below.

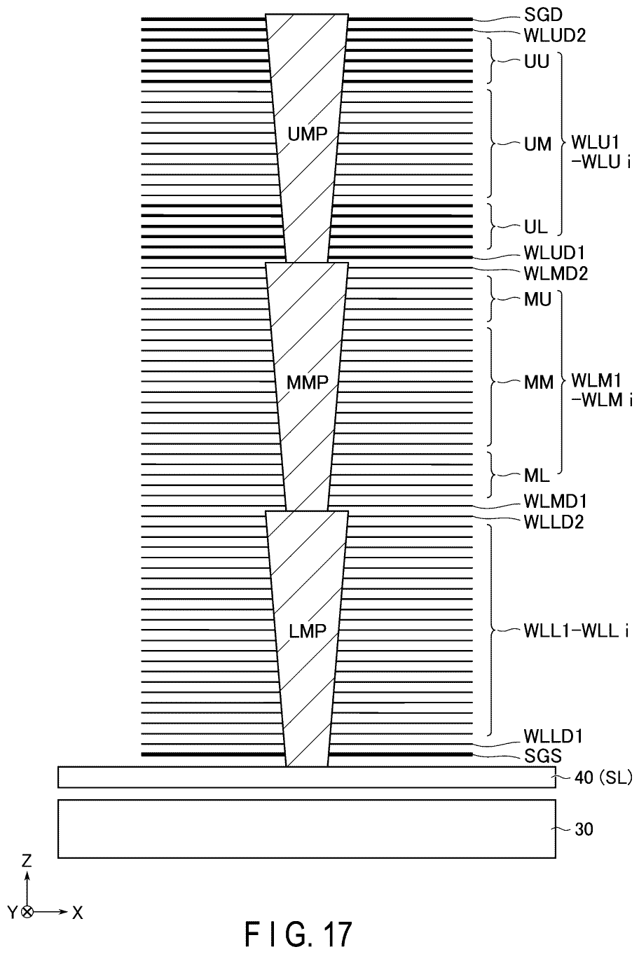

First, the structure of the word lines WL according to the first modification will be described with reference to FIG. 17. The first modification is an example in which the film thickness of the lower word lines UL is formed thick in addition to forming the film thickness of the upper word lines UU thick.

FIG. 17 is a cross-sectional view showing an outline of structures of the memory pillars and the word lines according to the first modification. In the word lines WLU1 to WLUi and the word lines WLM1 to WLMi provided around the upper pillar UMP and the middle pillar MMP, the film thickness of each of the upper word lines UU and the lower word lines UL is thicker than the film thickness of each of the middle word lines UM. The film thickness of each of the upper word lines UU and the lower word lines UL is substantially equal, that is, substantially the same. In addition, the film thicknesses of the middle word lines UM, the upper word lines MU, the middle word lines MM, and the lower word lines ML are substantially equal, that is, substantially the same.

The film thickness of each of the dummy word lines WLUD1 and WLUD2 is thicker than the film thickness of each of the middle word lines UM. The film thickness of each of the dummy word lines WLUD1 and WLUD2 is substantially equal to, that is, substantially the same as the film thickness of each of the upper word lines UU. The film thickness of each of the dummy word lines WLMD1 and WLMD2 is substantially equal to, that is, substantially the same as the film thickness of each of the middle word lines UM. The film thickness of a selection gate line SGD is thicker than the film thickness of each of the upper word lines UU.

The film thickness of each of the word lines WLL1 to WLLi provided around the lower pillar LMP is substantially equal to, that is, substantially the same as the film thickness of each of the middle word lines UM. Similarly, the film thickness of each of the dummy word lines WLLD1 and WLLD2 is substantially equal to, that is, substantially the same as the film thickness of each of the middle word lines UM. In addition, the film thickness of a selection gate line SGS is thicker than the film thickness of each of the upper word lines UU.

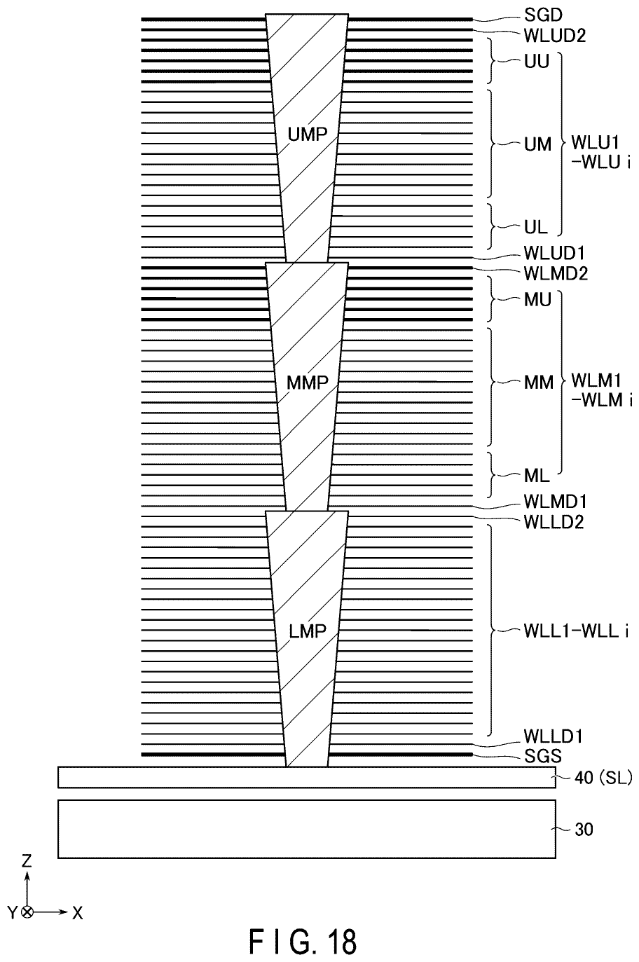

Next, the structure of the word lines WL according to the second modification will be described with reference to FIG. 18. The second modification is an example in which the film thickness of the upper word lines MU provided around the middle pillar MMP is formed thick in addition to forming the film thickness of the upper word lines UU thick.

FIG. 18 is a cross-sectional view showing an outline of structures of the memory pillars and the word lines according to the second modification. In the word lines WLU1 to WLUi and the word lines WLM1 to WLMi provided around the upper pillar UMP and the middle pillar MMP, the film thickness of each of the upper word lines UU and MU is thicker than the film thickness of each of the middle word lines UM. The film thickness of each of the upper word lines UU and the upper word lines MU is substantially equal, that is, substantially the same. In addition, the film thicknesses of the middle word lines UM, the lower word lines UL, the middle word lines MM, and the lower word lines ML are substantially the same, that is, substantially the same.

The film thickness of each of the dummy word lines WLUD2 and WLMD2 is thicker than the film thickness of each of the middle word lines UM. The film thicknesses of the dummy word lines WLUD2 and WLMD2 are substantially equal, that is, substantially the same. The film thickness of each of the dummy word lines WLUD1 and WLMD1 is substantially equal to, that is, substantially the same as the film thickness of each of the middle word lines UM. The film thickness of a selection gate line SGD is thicker than the film thickness of each of the upper word lines UU.

The film thickness of each of the word lines WLL1 to WLLi provided around the lower pillar LMP is substantially equal to, that is, substantially the same as the film thickness of each of the middle word lines UM. Similarly, the film thickness of each of the dummy word lines WLLD1 and WLLD2 is substantially equal to, that is, substantially the same as the film thickness of each of the middle word lines UM. In addition, the film thickness of a selection gate line SGS is thicker than the film thickness of each of the upper word lines UU.

### 2.3 Effects of Second Embodiment

According to the second embodiment, a semiconductor memory device capable of improving operation reliability can be provided.

Hereinafter, effects of the second embodiment will be described.

According to the second embodiment, among the plurality of stacked word lines WL, the film thickness of the word lines of some layers in which defects such as a short circuit easily occur in the upper and lower word lines, that is, the upper word lines UU around the upper pillar UMP are thickened. In other words, the film thickness of the word lines WL included in the upper word lines UU is formed to be thicker than the film thickness of the word lines WL included in the middle word lines UM. With this configuration, at the time of processing the contact holes, it can be prevented that the contact hole passes through the target word line WL and reaching the word line WL below or reaching the vicinity of the word line WL below, and the occurrence of the above-described problems can be reduced.

According to the first modification, among the plurality of stacked word lines WL, the film thicknesses of the word lines of some layers in which defects such as a short circuit easily occur in the upper and lower word lines, that is, the upper word lines UU and the lower word lines UL around the upper pillar UMP are thickened. In other words, the film thicknesses of the word lines WL included in the upper word lines UU and the word lines WL included in the lower word lines UL are formed to be thicker than the film thickness of the word lines WL included in the middle word lines UM.

According to the second modification, among the plurality of stacked word lines, the film thicknesses of the word lines of some layers in which defects such as a short circuit easily occur in the upper and lower word lines, that is, the upper word lines UU around the upper pillar UMP and the upper word lines MU around the middle pillar MMP are thickened. In other words, the film thickness of the word lines WL included in the upper word lines UU and the film thickness of the word lines WL included in the upper word lines MU are formed to be thicker than the film thickness of the word lines WL included in the middle word lines UM.

With this configuration, at the time of processing the contact holes, it can be prevented that the contact hole passes through the target word line WL and reaching the word line WL below or reaching the vicinity of the word line WL below, and the occurrence of the above-described problems can be reduced.

As described above, according to the semiconductor memory device 10 of the second embodiment and the modifications, defects such as a short circuit occurring in the upper and lower word lines WL can be reduced, and the reliability of the operation is improved.

### 3. Third Embodiment

A semiconductor memory device according to a third embodiment will be described. In the third embodiment, an example in which the film thicknesses of upper word lines UU, middle word lines UM, and lower word lines UL around an upper pillar UMP are gradually reduced will be described. In the third embodiment, points different from the first embodiment will be mainly described.

### 3.1 Structure of Memory Pillars and Word Lines

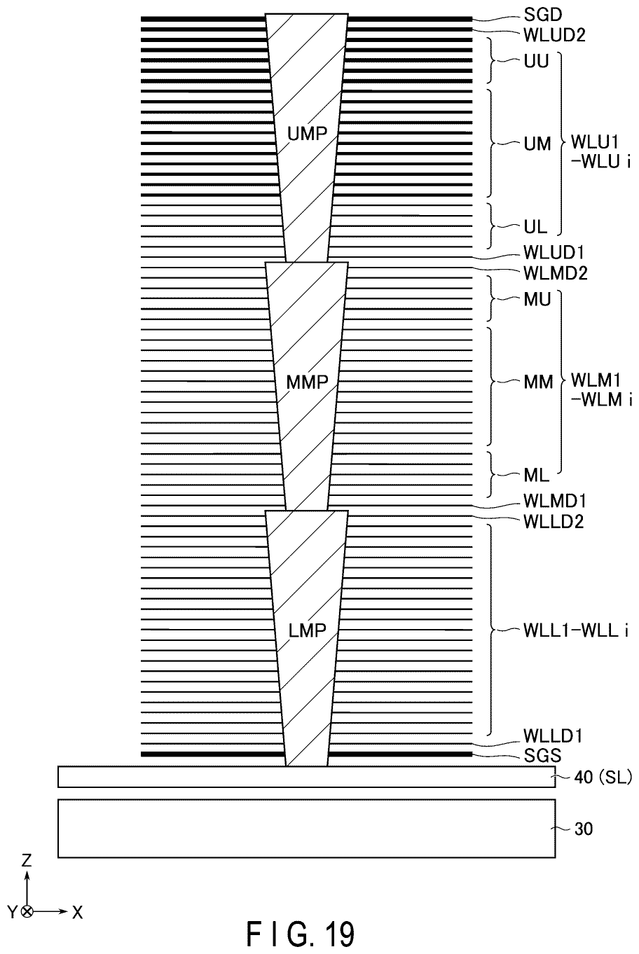

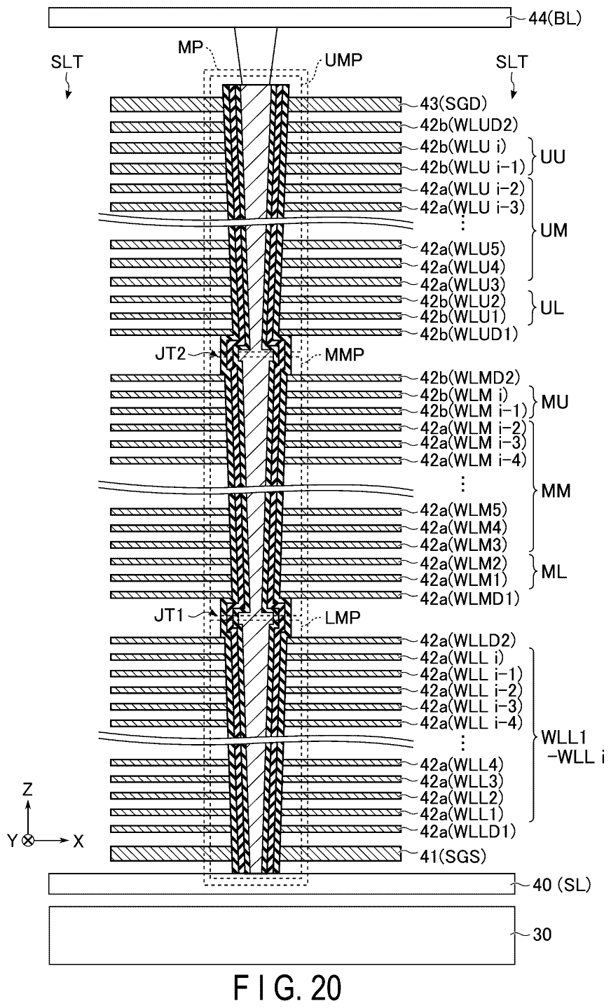

The structures of memory pillars MP and word lines WL in a semiconductor memory device 10 according to the third embodiment will be described with reference to FIGS. 19 and 20. FIG. 19 is a cross-sectional view showing an outline of structures of the memory pillars and the word lines in the semiconductor memory device 10. FIG. 20 is a cross-sectional view showing details of the structures of the memory pillars and the word lines in the semiconductor memory device 10.

Hereinafter, the film thicknesses of the word lines WL provided around the lower pillar LMP, the middle pillar MMP, and the upper pillar UMP will be described.

As illustrated in FIGS. 19 and 20, in word lines WLU1 to WLUi and word lines WLM1 to WLMi, the film thickness of each of the upper word lines UU is thicker than the film thickness of each of the middle word lines UM. The film thickness of each of the middle word lines UM is thicker than the film thickness of each of the lower word lines UL. In other words, the film thicknesses of the upper word lines UU, the middle word lines UM, and the lower word lines UL gradually decrease in the described order.

The film thickness of each of upper word lines MU is substantially equal to, that is, substantially the same as the film thickness of each of the lower word lines UL. The film thicknesses of the upper word lines MU, middle word lines MM, and lower word lines ML are substantially equal, that is, substantially the same.

The film thickness of a dummy word line WLUD2 is thicker than the film thickness of each of the middle word lines UM. The film thickness of the dummy word line WLUD2 is substantially equal to, that is, substantially the same as the film thickness of each of the upper word lines UU. The film thickness of each of dummy word lines WLUD1, WLMD1, and WLMD2 is substantially equal to, that is, substantially the same as the film thickness of each of the upper word lines MU. The film thickness of a selection gate line SGD is thicker than the film thickness of each of the upper word lines UU.

The film thickness of each of word lines WLL1 to WLLi provided around the lower pillar LMP is substantially equal to, that is, substantially the same as the film thickness of each of the upper word lines MU,. Similarly, the film thickness of each of dummy word lines WLLD1 and WLLD2 is substantially equal to, that is, substantially the same as the film thickness of each of the upper word lines MU. In addition, the film thickness of a selection gate line SGS is thicker than the film thickness of each of the upper word lines UU. The film thickness of each of the upper word lines MU may be set to be thinner than the film thickness of each of the lower word lines UL.

The film thickness of the word lines to be thickened in the present embodiment is set to be thicker by about 0.5 to 3 nm than the film thickness of the word lines not to be thickened. For example, in a case where the film thickness of the word lines included in the lower word lines UL is 20 nm, the film thickness of the word lines included in the middle word lines UM is 20.5 to 23 nm, and the film thickness of the word lines included in the upper word lines UU is 21 to 26 nm. In a case where the film thickness of the word lines included in the lower word lines UL is 25 nm, the film thickness of the word lines included in the middle word lines UM is 25.5 to 28 nm, and the film thickness of the word lines included in the upper word lines UU is 26 to 31 nm.

The film thickness of the dummy word line WLUD2 is substantially equal to, that is, substantially the same as the film thickness of each of the upper word lines UU. In a case where the film thickness of the word lines included in the lower word lines UL is 20 nm, the film thickness of the dummy word line WLUD2 is 21 to 26 nm. In a case where the film thickness of the word lines included in the lower word lines UL is 25 nm, the film thickness of the dummy word line WLUD2 is 26 to 31 nm.

### 3.2 Effects of Third Embodiment

According to the third embodiment, a semiconductor memory device capable of improving operation reliability can be provided.

Hereinafter, effects of the third embodiment will be described.

According to the third embodiment, among the plurality of stacked word lines WL, the film thicknesses of the word lines of some layers in which defects such as a short circuit are likely to occur in the upper and lower word lines, that is, the upper word lines UU, the middle word lines UM, and the lower word lines UL around the upper pillar UMP are gradually reduced. In other words, the film thickness is gradually increased from the lower word lines UL toward the middle word lines UM and further toward the upper word lines UU. That is, the word lines WL included in the upper word lines UU are formed to be thicker than the film thickness of the word lines WL included in the middle word lines UM. Furthermore, the word lines WL included in the middle word lines UM are formed to be thicker than the film thickness of the word lines WL included in the lower word lines UL.

With this configuration, at the time of processing the contact holes, it can be prevented that the contact hole passes through the target word line WL and reaching the word line WL below or reaching the vicinity of the word line WL below, and the occurrence of the above-described problems can be reduced.

As described above, according to the semiconductor memory device 10 of the third embodiment, defects such as short circuits occurring in the upper and lower word lines WL can be reduced, and the reliability of the operation is improved.

### 4. Others

In the above embodiments, the NAND flash memory has been described as an example of the semiconductor memory device, but the present invention is not limited to the NAND flash memory, and can be applied to other general semiconductor memories having the same structure as the hookup region described in the embodiments, and furthermore, can be applied to various semiconductor devices other than the semiconductor memory. In addition, in the flowchart described in the above embodiment, the order of the processing can be changed as much as possible.

Although some embodiments of the present invention have been described, these embodiments have been presented as examples, and are not intended to limit the scope of the invention. These embodiments can be implemented in various other forms, and various omissions, substitutions, and changes can be made without departing from the gist of the invention. These embodiments and modifications thereof are included in the scope and gist of the invention and are included in the invention described in the claims and the equivalent scope thereof.

What is claimed is:

1. A semiconductor memory device comprising:
a first plurality of word lines stacked above a substrate;
a second plurality of word lines stacked above the first plurality of word lines;
a selection gate line provided above the second plurality of word lines;
a first pillar provided above the substrate and penetrating the first plurality of word lines in a first direction orthogonal to an upper surface of the substrate; and
a second pillar provided above the first pillar and penetrating the second plurality of word lines and the selection gate line in the first direction,
wherein the second plurality of word lines include an upper word line disposed around an upper layer portion of the second pillar, a middle word line disposed around a middle layer portion below the upper layer portion, and a lower word line disposed around a lower layer portion below the middle layer portion, and
a film thickness of the upper word line is thicker than a film thickness of the middle word line.

2. The semiconductor memory device according to claim 1, wherein
the upper word line is disposed in a vicinity of an upper end of the second pillar,
the lower word line is disposed in a vicinity of a boundary between the first pillar and the second pillar, and
the middle word line is disposed between the upper word line and the lower word line.

3. The semiconductor memory device according to claim 2, further comprising
a joint portion provided between the first pillar and the second pillar,
wherein the lower word line is disposed in a vicinity of the joint portion.

4. The semiconductor memory device according to claim 1, further comprising
a dummy word line disposed between the upper word line and the selection gate line,
wherein a film thickness of the dummy word line is thicker than a film thickness of the middle word line.

5. The semiconductor memory device according to claim 4, further comprising
a row decoder that supplies voltage,
wherein the second plurality of word lines and the selection gate line are electrically connected to the row decoder, and
the dummy word line is not electrically connected to the row decoder.

6. The semiconductor memory device according to claim 1, wherein
each of portions where the second pillar intersects the second plurality of word lines functions as a memory cell, and
a portion where the second pillar intersects the selection gate line functions as a selection transistor.

7. The semiconductor memory device according to claim 6, wherein
the memory cell is configured to be capable of storing data.

8. The semiconductor memory device according to claim 4, wherein
a portion where the second pillar intersects the dummy word line is configured not to store data.

9. The semiconductor memory device according to claim 1, wherein
a film thickness of the lower word line is thicker than a film thickness of the middle word line.

10. The semiconductor memory device according to claim 9, wherein
a film thickness of an upper word line disposed around an upper layer portion of the first pillar among the first plurality of word lines is thicker than a film thickness of the middle word line.

11. The semiconductor memory device according to claim 10, wherein
the upper word line around the upper layer portion of the first pillar is disposed in a vicinity of a boundary between the first pillar and the second pillar.

12. The semiconductor memory device according to claim 1, wherein
a film thickness of the upper word line disposed around an upper layer portion of the first pillar among the first plurality of word lines is thicker than a film thickness of the middle word line.

13. The semiconductor memory device according to claim 12, wherein
the upper word line around the upper layer portion of the first pillar is disposed in a vicinity of a boundary between the first pillar and the second pillar.

14. The semiconductor memory device according to claim 1, wherein
a film thickness of the middle word line is thicker than a film thickness of the lower word line.

15. A semiconductor memory device comprising:
a first plurality of word lines stacked above a source line;
a second plurality of word lines stacked above the first plurality of word lines;
a selection gate line provided above the second plurality of word lines;
a first pillar provided above the source line and penetrating the first plurality of word lines in a first direction orthogonal to an upper surface of the source line; and
a second pillar provided above the first pillar and penetrating the second plurality of word lines and the selection gate line in the first direction,
wherein the second plurality of word lines include an upper word line disposed around an upper layer portion of the second pillar, a middle word line disposed around a middle layer portion below the upper layer portion, and a lower word line disposed around a lower layer portion below the middle layer portion, and
a film thickness of the upper word line is thicker than a film thickness of the middle word line.

16. The semiconductor memory device according to claim 15, wherein
the upper word line is disposed in a vicinity of an upper end of the second pillar,
the lower word line is disposed in a vicinity of a boundary between the first pillar and the second pillar, and
the middle word line is disposed between the upper word line and the lower word line.

17. The semiconductor memory device according to claim 15, wherein
a film thickness of the lower word line is thicker than a film thickness of the middle word line.

18. The semiconductor memory device according to claim 17, wherein
a film thickness of an upper word line disposed around an upper layer portion of the first pillar among the first plurality of word lines is thicker than the film thickness of the middle word line.

19. The semiconductor memory device according to claim 18, wherein
the upper word line around the upper layer portion of the first pillar is disposed in a vicinity of a boundary between the first pillar and the second pillar.

20. The semiconductor memory device according to claim 15, wherein
a film thickness of the middle word line is thicker than a film thickness of the lower word line.
